(19) United States
(12) Patent Application Publication
(10) Pub. No.: US 2021/0313503 A1
(43) Pub. Date: Oct. 7, 2021

(54) FUNCTIONALLY GRADED ORGANIC THERMOELECTRIC MATERIALS AND USES THEREOF

(71) Applicant: The University of Chicago, Chicago, IL (US)

(72) Inventors: Shrayesh N. Patel, Chicago, IL (US); Tengzhou Ma, Chicago, IL (US); William F. Kent, Chicago, IL (US); Garrett K. Grocke, Chicago, IL (US)

(21) Appl. No.: 17/301,403

(22) Filed: Apr. 1, 2021

Related U.S. Application Data
(60) Provisional application No. 63/003,749, filed on Apr. 1, 2020.

(51) Int. Cl. H01L 35/24; H01L 35/34; H01L 35/32

(52) U.S. Cl. CPC H01L 35/24; C08L 65/00; H01L 35/32; H01L 35/34

(57) ABSTRACT

The present disclosure relates to functionally graded thermoelectric materials including an organic conducting polymer. In particular, the material includes a molecular dopant that can be spatially distributed in a controlled pattern within the material. Methods of making such materials and devices including such materials are also described herein.

### CROSS-REFERENCE TO RELATED APPLICATION

This application claims the benefit of U.S. Provisional Patent Application No. 63/003,749, filed Apr. 1, 2020, which is incorporated herein by reference in its entirety.

### STATEMENT OF GOVERNMENT INTEREST

This invention was made with Government support under Contract No. DMR-1420709 awarded by the National Science Foundation. The Government has certain rights in the invention.

### FIELD

The present disclosure relates to functionally graded thermoelectric materials including an organic conducting polymer. In particular, the material includes a molecular dopant that can be spatially distributed in a controlled pattern within the material. Methods of making such materials and devices including such materials are also described herein.

### BACKGROUND

Organic thermoelectric materials could be viable alternatives to inorganic semiconductor platforms. Molecular doping remains essential in order to provide desired electronic transport properties within the bulk organic polymer. Yet, in some instances, the doping process itself can limit control over the desired functional and structural characteristics of the material. Accordingly, there is a need for additional processes and advanced materials that possess controlled doping characteristics.

### SUMMARY

The present disclosure relates to a functionally graded material (FGM) having spatial compositional control of molecular dopants dispersed within an organic conducting polymer. In particular, the spatial distribution of the dopant can vary within the material, and this heterogenous distribution can be designed to tune the material's properties (e.g., macroscopic charge transport properties). In some embodiments, the spatial distribution is a continuous gradient along a dimension of the material.

Methods of making such materials are also provided. Of note, the methods employ the molecular dopant in a vapor form, in which the extent of doping (e.g., the spatial concentration of the dopant) relies on controlling access of the vapor to the polymer to be doped (e.g., by way of controlling spatial access to regions of the polymer and/or controlling the doping time).

Devices including such materials are also described herein. In particular, the FGM can be electrically connected to interconnects, thereby providing a thermoelectric device. In some embodiments, the FGM is characterized by efficient heat distribution, which in turn provides larger cooling temperature gradients and improved cooling properties. Thus, semiconducting polymers, such as FGMs described herein, could serve as an enabling platform for the development of more efficient organic thermoelectric devices. For example, polymeric thermoelectrics have the potential to be used for local temperature control (e.g., as in Peltier coolers).

Accordingly, in a first aspect, the present disclosure encompasses a functionally graded material (e.g., a functionally graded thermoelectric material) including: an organic conducting polymer; and a molecular dopant. In particular embodiments, the molecular dopant is spatially distributed within the polymer in a continuous manner along at least 20% of a dimension of the material (e.g., along at least 20%, 25%, 30%, 35%, 40%, 45%, 50%, 60%, 70%, 80%, 90%, or 100%). In other embodiments, the polymer is provided as a film (e.g., having a thickness of from about 10 nm to 100 nm, or any described herein).

In some embodiments, the molecular dopant is spatially distributed in a controlled pattern across a surface of the polymer. In particular embodiments, the controlled pattern includes a step gradient (e.g., having a plurality of steps) or a linear gradient or a sigmoidal gradient or a bell curve gradient (e.g., having a concentration profile that extends from low to high to low concentration, or from high to low to high concentration). In some embodiments, the controlled pattern extends over the surface of the polymer along a dimension (e.g., an in-plane dimension) of from about 0.5, 1, 2, 3, 4, 5, 10, 15, 20 mm, or more, as well as any other distance described herein. In other embodiments, the controlled pattern extends over the surface of the polymer along at least 10%, 20%, 30%, 40%, 50%, 60%, 70%, 80%, or 90% of a linear dimension (e.g., a linear in-plane dimension) of the material.

In some embodiments, the dopant is capable of being introduced in a vapor phase to the polymer.

In a second aspect, the present disclosure features a device including at least one thermoelectric element. In some embodiments, the thermoelectric element includes: a first interconnect and a second interconnect, wherein the first and second interconnects include a conductive material; and a functionally graded thermoelectric material that is electrically connected to the first and second interconnects.

The functionally graded thermoelectric material can be any described herein. In particular embodiments, the functionally graded thermoelectric material includes an organic conducting polymer and a molecular dopant, wherein the molecular dopant is spatially distributed within the polymer in a continuous manner along at least about 20% of a dimension of the material.

In other embodiments, the device further includes a plurality of thermoelectric elements that are electrically connected in series and thermally connected in parallel.

In yet other embodiments, the device further includes a top substrate and a bottom substrate, wherein the one or more thermoelectric elements are disposed between the top and bottom substrate. In some embodiments, the device is configured to provide heat flow between the top and bottom substrate and vertically through the FGM disposed between the first and second interconnects. In other embodiments, the device is configured to provide heat flow laterally through the FGM disposed between the first and second interconnects.

In some embodiments, the device further includes a further thermoelectric material that is electrically connected to the second interconnect and a third interconnect, wherein the third interconnect includes a conductive material. In particular embodiments, the functionally graded thermoelectric material includes an n-type dopant, and the further thermoelectric material includes a p-type dopant. In other embodiments, the further thermoelectric material includes a further functionally graded thermoelectric material (e.g., having an organic conducting polymer and a molecular dopant that is a p-type dopant).

In a third aspect, the present disclosure features a method of making a functionally graded material (e.g., a functionally graded thermoelectric material), the method including: introducing a molecular dopant to an organic conducting polymer, wherein the molecular dopant is in a vapor form. In some embodiments, the method provides a material, in which the molecular dopant is spatially distributed within the polymer.

In some embodiments, the method further includes (e.g., prior to the introducing step): depositing or casting a solution including the polymer, thereby forming a film. In other embodiments, the method further includes (e.g., prior to the introducing step or after the casting step): annealing the polymer at a temperature of from about 150° C. to about 250° C. In particular embodiments, the annealing step provides an annealed polymer having increased crystallinity, as compared to a polymer prior to annealing.

In other embodiments, the method further includes (e.g., after the depositing step but prior to the introducing step): covering a surface of the polymer with a mask, thereby providing an exposed portion. In yet other embodiments, the mask is in contact with the surface of the polymer. In some embodiments, the mask is separated from the surface of the polymer by any useful distance (e.g., from about 5 μm to about 100 μm, such as from 5 μm to 20 μm, 5 μm to 50 μm, 5 μm to 75 μm, 10 μm to 20 μm, 10 μm to 50 μm, 10 μm to 75 μm, 10 μm to 100 μm, 20 μm to 50 μm, 20 μm to 75 μm, 20 μm to 100 μm, 40 μm to 50 μm, 40 μm to 75 μm, or 40 μm to 100 μm).

In some embodiments, the mask has a wedge geometry, in which a side of the wedge forms a proximal surface in proximity to the surface of the polymer. In other embodiments, a region between the proximal surface of the mask and the surface of the polymer provides a constrained region accessible to the dopant.

In other embodiments, the method includes (e.g., as the introducing step): introducing the molecular dopant to the exposed portion. In some embodiments, the method includes (e.g., as part of the introducing step): heating the dopant to a temperature to promote sublimation of the dopant (e.g., in proximity to the polymer). In other embodiments, the method includes (e.g., as part of the introducing step): delivering the dopant in vapor form to a chamber including the polymer.

In some embodiments, the method provides a material, in which the molecular dopant is spatially distributed in a controlled pattern across the surface of the polymer and/or within the exposed portion of the polymer. In some embodiments, the controlled pattern includes a step gradient or a linear gradient or a sigmoidal gradient or a bell curve gradient.

In a fourth aspect, the present invention features a method of making a functionally graded material (e.g., a functionally graded thermoelectric material). In some embodiments, the method includes: depositing an organic conducting polymer on a substrate; covering a surface of the polymer with a mask, thereby providing an exposed portion; and introducing a molecular dopant to the exposed portion, wherein the molecular dopant is in vapor form. In some embodiments, the method thereby provides the functionally graded thermoelectric material.

In some embodiments, the molecular dopant is spatially distributed within the polymer. In particular embodiments, a crystallinity of the film is substantially maintained before and after introducing the dopant.

In some embodiments, the introducing step further includes: heating the dopant to a temperature to promote sublimation of the dopant. In other embodiments, the introducing step further includes: delivering the dopant in a vapor form to a chamber including the polymer.

In other embodiments, the depositing step provides a film. In yet other embodiments, the depositing step includes: casting a solution including the polymer on the substrate, thereby forming a film.

In some embodiments, the mask is in contact with the surface of the polymer. In other embodiments, the mask is separated from the surface of the polymer by a distance. In yet other embodiments, the mask has a wedge geometry, in which a side of the wedge forms a proximal surface in proximity to the surface of the polymer. In particular embodiments, a region between the proximal surface of the mask and the surface of the polymer provides a constrained region accessible to the dopant.

In some embodiments, the method provides a material in which the molecular dopant is spatially distributed in a controlled pattern across a surface of the polymer. In particular embodiments, the controlled pattern includes a step gradient (e.g., having a plurality of steps) or a linear gradient or a sigmoidal gradient or a bell curve gradient. In some embodiments, the controlled pattern extends over the surface of the polymer along a dimension (e.g., an in-plane dimension) of from about 1, 2, 3, 4, 5, 10, 15, 20 mm, or more, as well as any other distance described herein. In other embodiments, the controlled pattern extends over the surface of the polymer along at least 10%, 20%, 30%, 40%, 50%, 60%, 70%, 80%, or 90% of a linear dimension (e.g., a linear in-plane dimension) of the material.

In other embodiments, the method further includes (e.g., after the depositing step): annealing the polymer at a temperature of from about 150° C. to about 250° C. In particular embodiments, the annealing step provides an annealed polymer having increased crystallinity, as compared to a polymer prior to annealing. In particular embodiments, a crystallinity of the annealed film is substantially maintained before and after introducing the dopant.

In any embodiment herein, the molecular dopant is spatially distributed within the polymer in a continuous manner along at least 10% of a dimension of the material (e.g., along at least 20%, 25%, 30%, 35%, 40%, 45%, 50%, 60%, 70%, 80%, 90%, or 100%). In some embodiments, the change is over along about 10% to about 100% of a dimension of the material, including from 10% to 100%, 15% to 100%, 20% to 100%, 25% to 100%, 30% to 100%, 35% to 100%, 40% to 100%, 45% to 100%, 50% to 100%, 50% to 100%, 60% to 100%, 70% to 100%, 80% to 100%, 90% to 100%, 10% to 95%, 15% to 95%, 20% to 95%, 25% to 95%, 30% to 95%, 35% to 95%, 40% to 95%, 45% to 95%, 50% to 95%, 60% to 95%, 70% to 95%, or 80% to 95%).

In any embodiment herein, the molecular dopant is spatially distributed in a controlled pattern across a surface of the polymer. In some embodiments, the controlled pattern includes a step gradient (e.g., having a plurality of steps), a linear gradient, a sigmoidal gradient, or a bell curve gradient.

In any embodiment herein, the polymer is provided as a film.

In any embodiment herein, the polymer includes a conjugated polymer.

In any embodiment herein, the polymer is capable of being cast onto a substrate from a solution.

In any embodiment herein, the polymer includes an optionally substituted thiophene, an optionally substituted thienothiophene, an optionally substituted benzodithiophene, an optionally substituted cyclopentadithiophene, an optionally substituted bithiophene, an optionally substituted quaterthiophene, an optionally substituted isothianaphthene, an optionally substituted ethylenedioxythiophene, as well as combinations thereof.

In any embodiment herein, the polymer includes an optionally substituted polythiophene.

In any embodiment herein, the polymer is substituted with an optionally substituted C₃₋₂₄ alkyl (e.g., linear, branched, and/or cyclic alkyl), an optionally substituted C₃₋₂₄ alkenyl (e.g., including one or more double bonds), an optionally substituted C₃₋₂₄ alkynyl, optionally substituted C₃₋₂₄ thioalkyl, an optionally substituted C₃₋₂₄ haloalkyl (e.g., including one or more halo), optionally substituted C₃₋₂₄ alkoxy, halo (e.g., fluoro, chloro, bromo, or iodo), as well as combinations thereof.

In any embodiment herein, the dopant sublimes at a temperature of from about 150° C. to about 250° C. at an ambient pressure.

In any embodiment herein, the dopant includes a p-type dopant or an n-type dopant.

In any embodiment herein, the dopant includes an optionally substituted quinodimethane, an optionally substituted naphthoquinodimethane, an optionally substituted perylene, an optionally substituted hexaazatriphenylene, and others, as well as ion forms thereof.

In any embodiment herein, the dopant is substituted with a halo (e.g., fluoro), cyano, ester, or a combination thereof. Additional details are described herein.

### Definitions

As used herein, the term “about” means +/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. Such an aliphatic can be unsubstituted or substituted with one or more groups, such as groups described herein for an alkyl group.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” and the prefix “alk” is meant a branched or unbranched saturated hydrocarbon group of 1 to 50 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₅₀ cycloalkyl) or acyclic. The alkyl group can be branched or unbranched. The alkyl group can also be substituted or unsubstituted. For example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) C₁₋₆ alkylsulfinyl (e.g., —S(O)-Ak, wherein Ak is optionally substituted C₁₋₆ alkyl); (3) C₁₋₆ alkylsulfonyl (e.g., —SO₂-Ak, wherein Ak is optionally substituted C₁₋₆ alkyl); (4) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (5) aryl; (6) arylalkoxy (e.g., —O-L-Ar, wherein L is a bivalent form of optionally substituted alkyl and Ar is optionally substituted aryl); (7) aryloyl (e.g., —C(O)—Ar, wherein Ar is optionally substituted aryl); (8) azido (e.g., —N₃); (9) cyano (e.g., —CN); (10) carboxyaldehyde (e.g., —C(O)H); (11) C₃₋₈ cycloalkyl (e.g., a monovalent saturated or unsaturated non-aromatic cyclic C₃₋₈ hydrocarbon group); (12) halo (e.g., F, Cl, Br, or I); (13) heterocyclyl (e.g., a 5-, 6- or 7-membered ring, unless otherwise specified, containing one, two, three, or four non-carbon heteroatoms, such as nitrogen, oxygen, phosphorous, sulfur, or halo); (14) heterocyclyloxy (e.g., —O-Het, wherein Het is heterocyclyl, as described herein); (15) heterocyclyloyl (e.g., —C(O)—Het, wherein Het is heterocyclyl, as described herein); (16) hydroxyl (e.g., —OH); (17)N-protected amino; (18) nitro (e.g., —NO₂); (19) oxo (e.g., ═O); (20) C₃₋₈ spirocyclyl (e.g., an alkylene or heteroalkylene diradical, both ends of which are bonded to the same carbon atom of the parent group); (21) C₁₋₆ thioalkoxy (e.g., —S-Ak, wherein Ak is optionally substituted C₁₋₆ alkyl); (22) thiol (e.g., —SH); (23) —CO₂R^{A}, where R^{A} is selected from the group consisting of (a) hydrogen, (b) C₁₋₆ alkyl, (c) C₄₋₁₈ aryl, and (d) (C₄₋₁₈ aryl) C₁₋₆ alkyl (e.g., -L-Ar, wherein L is a bivalent form of optionally substituted alkyl group and Ar is optionally substituted aryl); (24) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -L-Ar, wherein L is a bivalent form of optionally substituted alkyl group and Ar is optionally substituted aryl); (25) —SO₂R^{D}, where R^{D} is selected from the group consisting of (a) C₁₋₆ alkyl, (b) C₄₋₁₈ aryl, and (c) (C₄₋₁₈ aryl) C₁₋₆ alkyl (e.g., -L-Ar, wherein L is a bivalent form of optionally substituted alkyl group and Ar is optionally substituted aryl); (26) —SO₂NR^{E}R^{F}, where each of R^{E} and R^{F} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -L-Ar, wherein L is a bivalent form of optionally substituted alkyl group and Ar is optionally substituted aryl); and (27) —NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., L-Ar, wherein L is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -L-Cy, wherein L is a bivalent form of optionally substituted alkyl group and Cy is optionally substituted cycloalkyl, as described herein), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, C₁₋₂₄, C₁₋₃₂, C₁₋₃₈, or C₁₋₄₂ alkyl group.

By “alkylene” is meant a multivalent (e.g., bivalent) form of an alkyl group, as described herein. Non-limiting alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₁₋₃₂, C₁₋₃₈, C₁₋₄₂, C₁₋₅₀, C₂₋₃, C₂₋₆, C₂₋₁₂, C₂₋₁₆, C₂₋₁₈, C₂₋₂₀, C₂₋₂₄, C₂₋₃₂, C₂₋₃₈, C₂₋₄₂, or C₂₋₅₀ alkylene group. The alkylene group can be branched or unbranched. The alkylene group can also be substituted or unsubstituted. For example, the alkylene group can be substituted with one or more substitution groups, as described herein for alkyl.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system. Such an aromatic can be unsubstituted or substituted with one or more groups, such as groups described herein for an alkyl group. Yet other substitution groups can include aliphatic, haloaliphatic, halo, nitrate, cyano, sulfonate, sulfonyl, or others. Non-limiting aromatic can include aryl and heteroaryl groups.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents provided herein as possible substitutions for alkyl. In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “aryloxy” is meant —OR, where R is an optionally substituted aryl group, as described herein. In some embodiments, an unsubstituted aryloxy group is a C₄₋₁₈ or C₆₋₁₈ aryloxy group.

By “cyano” is meant a —CN group.

By “cycloalkyl” is meant a monovalent saturated or unsaturated non-aromatic cyclic hydrocarbon group of from three to ten carbons (e.g., C₃₋₈ or C₃₋₁₀), unless otherwise specified, and is exemplified by cyclopropyl, cyclobutyl, cyclopentyl, cyclohexyl, cycloheptyl, bicyclo[2.2.1.]heptyl, and the like. The term cycloalkyl also includes “cycloalkenyl,” which is defined as a non-aromatic carbon-based ring composed of three to ten carbon atoms and containing at least one double bound, i.e., C═C. Examples of cycloalkenyl groups include, but are not limited to, cyclopropenyl, cyclobutenyl, cyclopentenyl, cyclopentadienyl, cyclohexenyl, cyclohexadienyl, and the like. The cycloalkyl group can also be substituted or unsubstituted. For example, the cycloalkyl group can be substituted with one or more groups including those described herein for alkyl.

By “ester” as used herein is represented by the formula —OC(O)A₁ or —C(O)OA₁, where A₁ can be an optionally substituted aliphatic, as described herein. In some non-limiting embodiments, A₁ is optionally substituted alkyl.

By “halo” is meant F, Cl, Br, or I.

By “heteroaliphatic” is meant an aliphatic group, as defined herein, containing one, two, three, or four non-carbon heteroatoms (e.g., independently selected from the group consisting of nitrogen, oxygen, phosphorous, sulfur, selenium, or halo). The heteroaliphatic group can be substituted or unsubstituted. For example, the heteroaliphatic group can be substituted with one or more substitution groups, as described herein for alkyl.

By “heteroalkylene” is meant a bivalent form of an alkylene group, as defined herein, containing one, two, three, or four non-carbon heteroatoms (e.g., independently selected from the group consisting of nitrogen, oxygen, phosphorous, sulfur, selenium, or halo). The heteroalkylene group can be substituted or unsubstituted. For example, the heteroalkylene group can be substituted with one or more substitution groups, as described herein for alkyl.

By “heterocyclyl” is meant a 3-, 4-, 5-, 6- or 7-membered ring (e.g., a 5-, 6- or 7-membered ring), unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like.

By “ion” is meant an ionic form of a compound or structure (e.g., any formulas, compounds, or compositions described herein), in which the ionic form has a net electric charge. Thus, the ionic form can be a cation or an anion.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S M et al., “Pharmaceutical salts,” J. Pharm. Sci. 1977 January; 66(1):1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amine cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “attaching,” “attachment,” or related word forms is meant any covalent or non-covalent bonding interaction between two components. Non-covalent bonding interactions include, without limitation, hydrogen bonding, ionic interactions, halogen bonding, electrostatic interactions, π bond interactions, hydrophobic interactions, inclusion complexes, clathration, van der Waals interactions, and combinations thereof.

### BRIEF DESCRIPTION OF THE DRAWINGS

FIG. 1A-1B shows schematics of non-limiting functionally graded materials (FGMs). Provided are (A) non-limiting polymers provided as a neat film 101, FGMs 105, or a homogenously doped film 104; and (B) properties of a non-limiting FGM formed with poly(2,5-bis(3-tetradecylthio-phen-2-yl)thieno[3,2-b]thiophene) (PBTTT) as the polymer and 2,3,5,6-tetrafluoro-7,7,8,8-tetracyanoquinodimethane (F4TCNQ) as the molecular dopant.

FIG. 2A-2B shows schematics of non-limiting systems for making such FGMs. Provided are (A) a non-limiting system employing a molecular dopant provided in vapor form from a source 202, as well as a mask 206 in conjunction with a film 210 including the organic conducting polymer; and (B) another non-limiting system employing a mask 226 with a different geometry.

FIG. 3A-3B shows use of a non-limiting FGM in a thermoelectric device. Provided are (A) a schematic of an FGM as a film disposed between a cold side (at x=0) and a hot side (at x=L) of a thermoelectric device, as well as a depiction of the change in the Seebeck coefficient ax and electrical conductivity σₓ as a function of x (along a length L of the polymer film), in which the film has a spatial gradient of the dopant extending along x; and (B) a graph showing cooling temperature ΔT for a uniform film (denoted as “Uniform α”) and for a continuously graded (CG) film having a non-limiting gradient (denoted as “α₀/α_{L}=0.1”).

FIG. 4A-4E shows (A) the chemical structure of poly[2,5-bis(3-tetradecylthiophen-2-yl) thieno [3,2-b]thiophene] (PBTTT) and 2,3,5,6-tetrafluoro-7,7,8,8-tetracyanoquinodimethane (F4TCNQ); (B) a schematic of a non-limiting fabrication system to achieve a continuously graded (CG) PBTTT thin film; (C) a close-up view of the interface between the mask and the polymer film within the non-limiting fabrication system; (D) an image of a non-limiting CG PBTTT thin film; and (E) conductivity (measured by an array of interdigitated electrodes) as a function of distance along a non-limiting CG thin film.

FIG. 5A-5B shows non-limiting grazing incidence wide angle X-ray scattering (GIWAXS) images of (A) a neat film and (B) a doped film.

FIG. 6A-6B shows (A) out-of-plane (200) scattering peak profiles and (B) in-plane scattering profiles for a first reflection (1̅13̅) and a second reflection (110) across the continuously graded films every 400 μm.

FIG. 7A-7B shows (A) alkyl domain side chain spacing (d₁₀₀) and (B) R-stacking spacing (d₁₁₀) across non-limiting CG PBTTT thin films obtained from GIWAXS.

FIG. 8 shows a schematic of a non-limiting geometry for gold contacts, which was used to obtain Seebeck coefficients (α₁, α₂, α₃, and α₄) and conductivity measurements (σ₁, σ₂, σ₃, and σ₄).

FIG. 9A-9C shows Seebeck coefficient and conductivity profiles of continuously graded PBTTT thin films with (A) α_{L}/α₀=2.2, σ_{L/}σ₀=0.03; (B) α_{L}/α₀=3.4, σ_{L}/σ₀=0.006; and (C) α_{L}/α₀=7.3, σ_{L}/σ₀=0.0006.

FIG. 10A-10B shows predicted coefficient of performance (C.O.P.) of (A) continuously graded films and (B) both continuously graded films (solid lines) and uniform equivalents (dashed lines) with respect to current density j.

FIG. 11 shows a schematic of a non-limiting single p-type leg of a Peltier cooler with assigned heat contributions.

FIG. 12 shows cooling temperatures (ΔT) of a continuously graded film at various input current density j.

FIG. 13A-13C shows C.O.P. of continuously graded (CG) samples (solid lines) and their uniform equivalents (dashed lines) for films with (A) α_{L}/α₀=2.2; (B) α_{L}/α₀=3.4; and (C) α_{L}/α₀=7.3.

FIG. 14A-14C shows temperature profiles of continuously graded (CG) films (solid lines) and uniform equivalents (dashed lines) at a current density of 3 mA/mm² for films with (A) α_{L}/α₀=2.2; (B) α_{L}/α₀=3.4; and (C) α_{L}/α₀=7.3.

FIG. 15A-15B shows the predicted cooling temperatures (ΔT) of continuously graded (CG) samples and their equivalent uniform profiles (A) at a constant current density of 3×10⁻³ A/mm² and (B) at optimal current densities.

FIG. 16A-16B shows schematics of non-limiting thermoelectric devices 1600, 1650. Provided are schematics for (A) a non-limiting dual leg configuration and (B) a non-limiting uni-leg configuration.

FIG. 17 shows a schematic of a non-limiting workflow for fabrication of micron-sized interdigitated electrodes (IDEs).

### DETAILED DESCRIPTION OF THE INVENTION

The present disclosure relates to functionally graded thermoelectric materials having a controlled distribution of a molecular dopant within an organic conducting polymer, as well as methods of using and making such materials. Devices including such materials are also described herein.

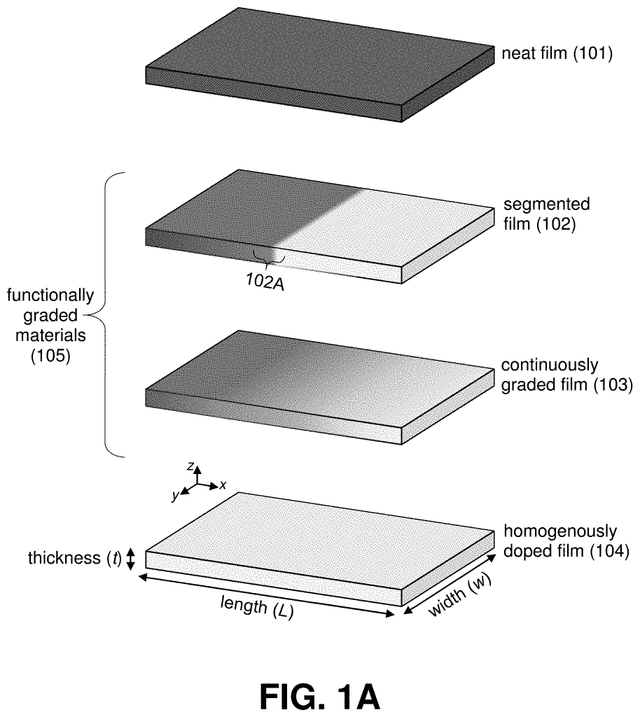

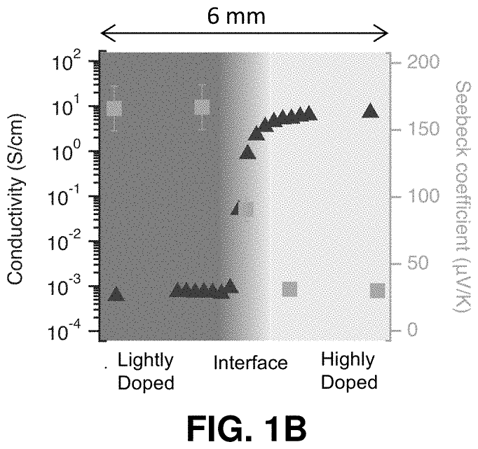

FIG. 1A provides a schematic of functionally graded materials, which provides a heterogenous material. For comparison, also provided are schematics of homogenous materials, such as a neat film 101 composed of an organic conducting polymer and a homogenously doped film 104, in which the surface of the film is uniformly doped with a molecular dopant. Such uniformity can include having a similar concentration of the dopant across the surface of the film (e.g., a concentration profile providing a continuous conductivity value along the length of the film, such as a length along an in-plane dimension, such as along the x-axis or within the x-y plane).

In contrast, a functionally graded material possesses an organic conducting polymer and a molecular dopant, in which the molecular dopant is spatially distributed within the polymer. This spatial distribution can be a controlled pattern across a surface of the polymer. In one instance, the pattern extends along a dimension of the polymer (e.g., along an in-plane dimension, in which the plane of interest is the x-y plane and the in-plane dimension is a length L or a width w, as seen in FIG. 1A). In another instance, the pattern minimally extends or does not extend along an out-of-plane dimension of the polymer (e.g., along an out-of-plane dimension, such as a thickness t determined along the z-axis, as seen in FIG. 1A).

The controlled pattern can include any useful gradient, in which the concentration of the dopant changes over the length. In some non-limiting instance, a molar ratio (MR) of the dopant to a monomer (of the polymer) is from about 0.01 to about 0.7 (e.g., of from about 0.01 to 0.05, 0.01 to 0.1, 0.01 to 0.2, 0.01 to 0.3, 0.01 to 0.4, 0.01 to 0.5, 0.02 to 0.05, 0.02 to 0.1, 0.02 to 0.2, 0.02 to 0.3, 0.02 to 0.4, 0.02 to 0.5, 0.02 to 0.6, 0.02 to 0.7, 0.04 to 0.05, 0.04 to 0.1, 0.04 to 0.2, 0.04 to 0.3, 0.04 to 0.4, 0.04 to 0.5, 0.4 to 0.6, 0.4 to 0.7, 0.05 to 0.1, 0.05 to 0.2, 0.05 to 0.3, 0.05 to 0.4, 0.05 to 0.5, 0.05 to 0.6, 0.05 to 0.7, 0.07 to 0.1, 0.07 to 0.2, 0.07 to 0.3, 0.07 to 0.4, 0.07 to 0.5, 0.07 to 0.6, and 0.07 to 0.7, as well as any useful range therebetween).

In some embodiments, the controlled pattern can be of any useful spatial geometry. In one instance, the controlled pattern is linear gradient (having a single step) or a step gradient (having a plurality of steps) that extends along a dimension of the polymer. In some embodiments, each step defines a transition in dopant concentration, and this transition extends over the surface of the polymer along a dimension (e.g., length and/or width) of from about 0.1, 0.5, 1, 2, 3, 4, or 5 mm, as well as ranges therebetween (e.g., from about 0.1 mm to 5 mm, such as 0.1 mm to 0.5 mm, 0.1 mm to 1 mm, 0.1 mm to 2 mm, 0.1 mm to 3 mm, 0.1 mm to 4 mm, 0.5 mm to 1 mm, 0.5 mm to 2 mm, 0.5 mm to 3 mm, 0.5 mm to 4 mm, 0.5 mm to 5 mm, 1 mm to 2 mm, 1 mm to 3 mm, 1 mm to 4 mm, 1 mm to 5 mm, 2 mm to 3 mm, 2 mm to 4 mm, or 2 mm to 5 mm). In other embodiments, the controlled pattern is a linear gradient or a sigmoidal gradient or a bell curve gradient that extends along a dimension (e.g., length and/or width) of the polymer.

Such controlled patterns can extend along any useful dimension (e.g., an in-plane dimension) and to any useful extent of that dimension (e.g., along a dimension of from about 1, 2, 3, 4, 5, 10, 15, 20 mm, or more). In other embodiments, the controlled pattern extends over the surface of the polymer along at least 10%, 20%, 30%, 40%, 50%, 60%, 70%, 80%, or 90% of a linear dimension (e.g., an in-plane dimension) of the material.

As seen in FIG. 1A, non-limiting FGMs 105 can include a segmented film 102 having a pattern, in which the dopant is spatially distributed within the polymer (e.g., along a surface of the polymer in the x-y plane or along the x-axis for the film). The pattern can include a region 102A along a dimension (e.g., length) of the material in which the concentration of the dopant changes in a step gradient. Another non-limiting FGM includes a continuously graded film 103, in which the pattern provides a dopant concentration that changes along a large portion of the desired dimension of the material (e.g., over at least about 20%, 30%, 40%, 50%, 60%, 70%, 80%, or 90% of the length of the material; such as a change along about 20% to about 100% of the material, including from 25% to 100%, 30% to 100%, 35% to 100%, 40% to 100%, 45% to 100%, 50% to 100%, 50% to 100%, 60% to 100%, 70% to 100%, 80% to 100%, 90% to 100%, 20% to 95%, 25% to 95%, 30% to 95%, 35% to 95%, 40% to 95%, 45% to 95%, 50% to 95%, 60% to 95%, 70% to 95%, or 80% to 95%). As would be understood to a skilled artisan, an FGM could encompass any useful heterogenous pattern of the dopant within the polymer (e.g., a pattern along the length and/or width of the surface, in which the pattern is a step gradient, a linear gradient, a sigmoidal gradient, a sinusoidal gradient, a bell curve gradient, etc.).

Furthermore, such controlled patterns can be defined by the electronic properties attributed by the pattern. Thus, in one non-limiting embodiment, the controlled pattern provides a change in conductivity that is spatially dependent. For instance, the pattern can provide a difference or change in conductivity along a dimension (e.g., an in-plane dimension) or a portion of that dimension, and the difference or change can be of from about 10⁻⁶ S cm⁻¹ (e.g., for an undoped polymer or minimally doped polymer) to about 10³ S cm⁻¹ (e.g., for a doped polymer or a maximally doped polymer). Accordingly, in one embodiment, a difference or change can be of from about 10⁻⁶ S cm⁻¹ (e.g., for an undoped polymer or minimally doped polymer) at a first position to about 10³ S cm⁻¹ (e.g., for a doped polymer or a maximally doped polymer) at a second position, in which the first and second positions are disposed along the in-plane dimension of the material. FIG. 1B provides a non-limiting FGM having a change in conductivity and Seebeck coefficient between a first position (e.g., lightly doped region) and a second position (e.g., highly doped region).

In another embodiment, the difference or change in conductivity along a dimension (e.g., an in-plane dimension) or a portion of that dimension can be a particular ratio. The ratio can be a ratio of the conductivity of the doped polymer to the conductivity in an undoped polymer, and a non-limiting ratio can be of from about 10 to about 10¹⁰. Accordingly, in one embodiment, a difference or change can be a ratio of from about 10 to about 10¹⁰, in which the ratio is the conductivity at a first position (e.g., for an undoped polymer or minimally doped polymer) to the conductivity at a second position (e.g., for a doped polymer or a maximally doped polymer), in which the first and second positions are disposed along the in-plane dimension of the material.

The polymer can be treated or processed in any useful manner. In one embodiment, the polymer can be annealed at an elevated temperature (e.g., from about 150° C. to about 250° C.). In particular embodiments, the annealed polymer has increased crystallinity, as compared to a polymer prior to annealing.

The present disclosure also encompasses methods of making such FGMs. In particular embodiments, the method includes use of the molecular dopant in vapor form. In one embodiment, the dopant sublimes at a temperature of from about 150° C. to 250° C. at ambient pressure. Accordingly, the method can include providing a dopant in vapor form or sublimating the dopant in situ in the presence of the polymer.

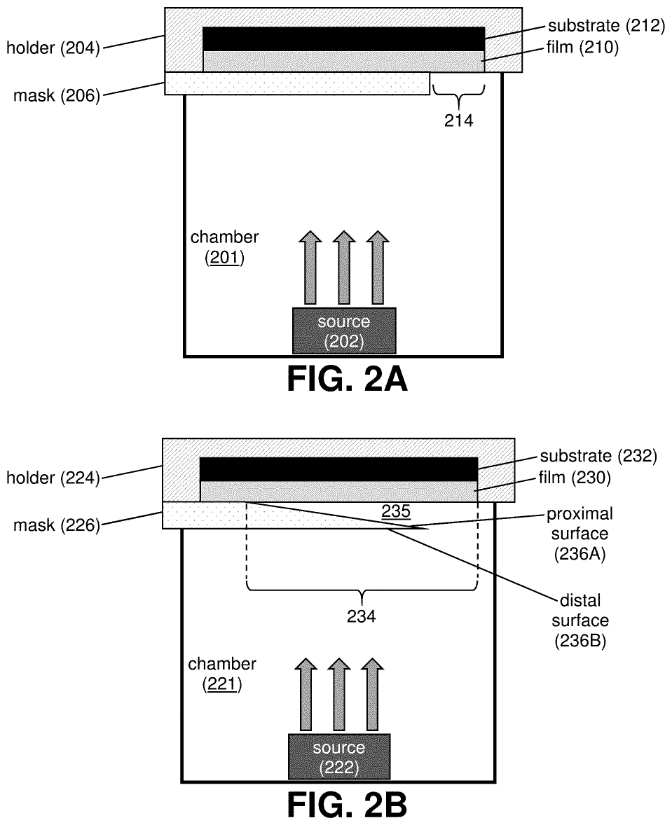

As seen in FIG. 2A, a non-limiting method can include introducing a molecular dopant to an organic conducting polymer, wherein the molecular dopant is in vapor form. As can be seen, the polymer is provided as a film 210 supported by a substrate 212, and the dopant is provided as a source 202. Both the film 210 and the source 202 are provided within a chamber 201. A holder 204 can be employed to support the film 210 and the substrate 212, as well as to define the interior volume of the chamber 201.

The vapor can be introduced in any useful form. In one embodiment, in situ sublimation can include heating the source 202, thereby filling the chamber 201 with a vapor form of the dopant and introducing the dopant to the film 210. The source can be heated, and/or the chamber can be heated. In one non-limiting embodiment, the source and/or chamber is heated to a temperature of from about 150° C. to about 250° C. at an ambient pressure. Alternatively, a lower temperature can be employed in a lower pressure environment; and a higher temperature in a higher pressure environment. The dopant in vapor form can be provided with or without flow within the chamber.

The pattern within the FGM can be controlled by controlling the extent to which the vapor can access the surface of the material. As seen in FIG. 2A, a mask 206 is employed to provide an exposed portion 214 of the film 210. In this manner, the dopant is primarily provided to this exposed portion 214, as well as to regions near this exposed region in which diffusion of the dopant could occur.

The mask can be designed to facilitate any useful pattern. For instance, the mask can include use of a solid material (e.g., an inert material, such as a perfluorinated polymer, such as Teflon, characterized by minimal diffusion of the dopant through the mask). A single mask can be employed multiple times at different positions in relation to the film, thereby defining the pattern. Alternatively, a series of different masks can be aligned with the film and employed to provide an exposed region at different locations of the film, thereby also defining the pattern.

The geometry of such a mask can be designed to provide desired vapor access to the exposed region of the polymer. In one instance, the mask is a solid bar that covers the polymer. Such covering can include contacting the polymer or providing a minimal space between the polymer and the mask, thereby minimizing diffusion of the vapor into that space. In another instance, the mask can include a sloped or curved surface to provide a constrained region that is accessible to the dopant, but in which the geometry of that constrained region affects the extent of diffusion of the dopant into that region. In addition to geometry, the material of the mask can be selected to provide desired diffusivity of the dopant through the mask. In certain embodiments, the mask may be configured to move relative to the film, e.g., during introduction of the dopant to the film.

In the compositions and methods herein, the polymer can be provided in any useful form. In one embodiment, the polymer is capable of being cast onto a substrate from a solution. Thus, the method can include dispensing a solution including the polymer onto a substrate. In other embodiments, the polymer is provided as a film, and the method includes providing such a film.

As seen in FIG. 2B, a non-limiting method can include providing the polymer as a film 230 supported by a substrate 232 and providing the dopant as a source 222 in any useful system. Here, the non-limiting system includes a holder 224 to support the film 230 and the substrate 232, as well as to define the interior volume of the chamber 221; and a source 222 disposed within the chamber 221.

The system further includes a mask 226 having a proximal surface 236A in proximity to the polymer and a distal surface 236B facing the source 222. Methods can include covering a surface of the polymer with a mask. As can be seen, the region between the proximal surface 236A of the mask 226 and the surface of the film 230 provides a constrained region 235 that is accessible to the dopant. This constrained region affects the diffusion profile of the dopant. For instance, under static flow conditions (or low flow conditions), the dopant would have to diffuse into the constrained region, and less of the dopant would access the narrower portion of the constrained region, as compared to the broader portion of this same region. In this manner, the geometry of the mask can affect the extent of doping in the exposed area 234 of the polymer.

By controlling the exposure time (i.e., the time for which the dopant is provided to the exposed area), the concentration gradient can be changed. By using both a mask (for spatial control) and exposure time (extent of dopant concentration), various patterns can be provided. In particular embodiments, the method can include a reiterative multistep process, in which each step is characterized by a particular position of the mask with respect to the polymer and/or a particular mask geometry and/or dopant exposure time. Such positions, geometries, and/or exposure times can be altered in each step to provide different overlaid patterns within the polymer or on a surface of the polymer.

The mask can possess any useful geometry to affect dopant access. In one instance, the mask has a wedge geometry, in which a side (e.g., the sloping side) of the wedge forms a proximal surface in proximity to the surface of the polymer. The sloping side of a wedge can be straight, curved (e.g., a convex or a concave curve), or stepped. In one instance, the sloping side of a wedge forms the distal surface of the mask, such that the sloping side faces away from the polymer. The mask can have any useful geometry, such as a wedge, a rectangular prism, a triangular prism, a cylinder, a pyramid, a cone, a hemisphere, a sphere, etc. In addition, the mask can have any useful surface or material modification, such as modification to surface chemistry (e.g., hydrophobicity, hydrophilicity, etc.), bulk and/or surface porosity, crosslinking density, etc.

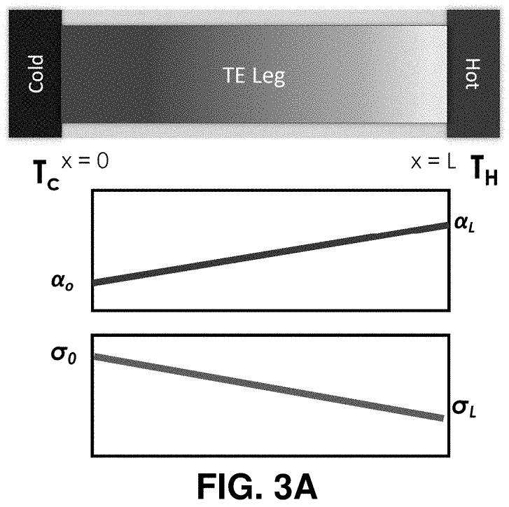

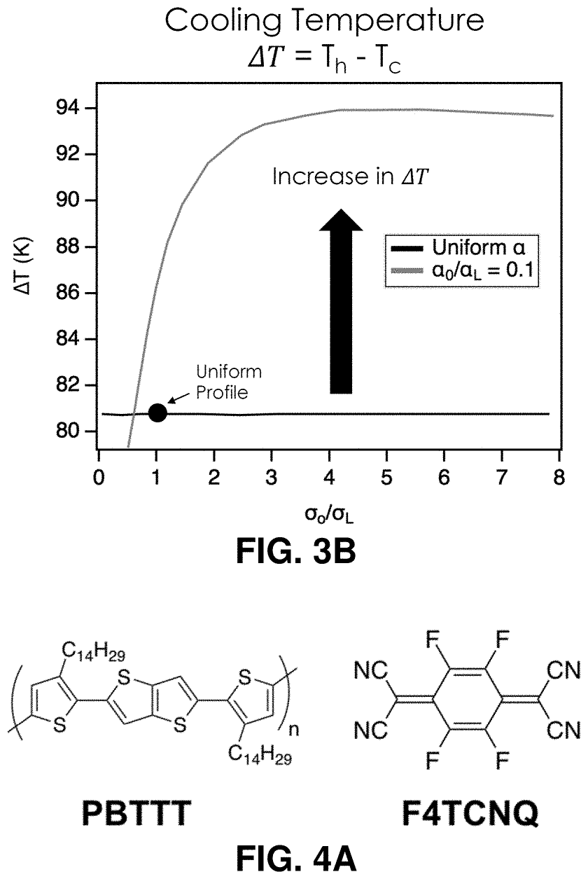

The FGMs herein can provide a gradient in functional properties that can depend on the dopant gradient within the polymer film. The gradient polymer, in turn, can be used within a thermoelectric (TE) leg of a device. As seen in FIG. 3A, the polymer film can extend within a temperature gradient disposed between a cold side (having a temperature T_{C}) and a hot side (having a temperature T_{H}), in which T_{C}<T_{H}. A dopant gradient can extend along the x-axis of the film, in which a polymer film can have a high dopant concentration in proximity to a cold side (at position x=0) and a low dopant concentration in proximity to the hot side (at a position x=L). The dopant gradient, in turn, can provide a gradient in functional properties, such as spatially dependent (e.g., x-dependent) values for electrical conductivity ax and the Seebeck coefficient αₓ.

By employing spatially controlled FGMs, device performance can be improved without a limitation on the particular type of material. In other words, spatial variation can be an orthogonal methodology (e.g., to material selection) that can be used to beneficially control thermoelectric properties of the film. As seen in FIG. 3B, spatial variation within the FGM can provide enhanced cooling properties, as compared to a uniform material having the same polymer and dopant present within the FGM.

The FGM can have any useful characteristic. In one embodiment, the FGM has an electrical conductivity σ of from about 10⁻⁵ S cm⁻¹ to more than 10³ S cm⁻¹ (e.g., from 10⁻⁴ to 100 S cm⁻¹ or 10⁻⁴ to 1000 S cm⁻¹). In one instance, the FGM has a first electrical conductivity σ₁ at a first position and a second electrical conductivity σ₂ at a second position, in which σ₁>σ₂ and in which a controlled pattern (e.g., any described herein) is disposed between the first and second positions. In particular embodiments, the dopant concentration within the film is higher at the first position, as compared to the second position. In other embodiments, the FGM has a thermal conductivity κ of from about 0.2 W m⁻¹ K⁻¹ to 0.5 W m⁻¹ K⁻¹.

In another embodiment, the FGM (or a device including the FGM) has a Seebeck coefficient α of from about 5 μV K⁻¹ to 10³ μV K⁻¹ (e.g., from 5 to 500 μV K⁻¹, 5 to 300 μV K⁻¹, or 10 to 500 μV K⁻¹). In one instance, the FGM has a first Seebeck coefficient α₁ at a first position and a second Seebeck coefficient α₂ at a second position, in which α₁<α₂ and in which a controlled pattern (e.g., any described herein) is disposed between the first and second positions. In particular embodiments, the dopant concentration within the film is higher at the first position, as compared to the second position.

In yet another embodiment, the FGM (or a device including the FGM) has a power factor PF of from about 0.1 μW m⁻¹ K⁻² to 2000 μW m⁻¹ K⁻² (e.g., from 1 to 2000 μW m⁻¹ K⁻², 1 to 1000 μW m⁻¹ K⁻², 1 to 500 μW m⁻¹ K⁻², 10 to 2000 μW m⁻¹ K⁻², 10 to 1000 μW m⁻¹ K⁻², 10 to 500 μW m⁻¹ K⁻², 50 to 2000 μW m⁻¹ K⁻², 50 to 1000 μW m⁻¹ K⁻², or 50 to 500 μW m⁻¹ K⁻²). The power factor be defined as PF=α²σ, where α is the Seebeck coefficient (or thermopower) [V K⁻¹] and σ is the electronic conductivity [S m⁻¹].

### Organic Conducting Polymers

In particular, the FGMs herein can include the use of organic polymers. Whereas inorganic-based materials typically require processing at high temperatures (e.g., about 1000 K or higher) and/or high pressure (e.g., about 50 MPa or higher), semiconducting organic polymers can be processed as a solution at fairly low temperatures to experimentally achieve FGMs. Non-limiting processing regimes for such organic polymers include about 340 K or higher (e.g., from 340 K to 380 K) at an ambient pressure (e.g., about 1 atm or about 760 mm Hg). Yet other non-limiting processing regimes for organic polymers can include, e.g., about 290 K to 500 K, 290 K to 400 K, 300 K to 500 K, 300 K to 400 K, and others.

The organic polymer, in turn, can be doped with a molecular dopant. Such doping can be spatially controlled, which in turn can enable control of carrier concentrations across the material. In one instance, molecular doping can include the use of a p-type dopant, such as a small organic acceptor. In use, electron transfer occurs between the host polymer and the dopant molecule, which modulates the carrier concentration and therefore tunes the thermoelectric properties of the doped material. Non-limiting molecular dopants are described herein.

The FGM herein can include any useful polymer. In particular embodiments, the polymer includes a conjugated polymer (e.g., having an alternating single-double bond structure). In other embodiments, the polymer includes an optionally substituted thiophene, an optionally substituted thienothiophene, an optionally substituted isothianaphthene, an optionally substituted ethylenedioxythiophene, or combinations thereof. In yet other embodiments, the polymer includes an optionally substituted polythiophene. Any of the polymers herein can be provided in neutral or charged forms (e.g., as ions, such as in cationic forms or anionic forms).

In some embodiments, the polymer (before and/or after doping) can be characterized by particular molecular or structural domains. In particular embodiments, the polymer includes long-range ordering (e.g., interconnectivity of locally ordered domains) and local ordering, as characterized by crystallite domains, lamellar stacking, and/or π-π stacking. Such long-range and local ordering can be characterized by grazing incidence wide angle X-ray scattering (GIWAXS) analysis, as well as peaks associated with such ordering (e.g., side-chain stacking (h00) peaks, backbone reflection (1̅13̅), reflection (110) related to the π-π stacking, lamellar (400) peaks, and others). In particular embodiments, such domains are maintained before and after doping. Without wishing to be limited by mechanism, maintaining such domains after doping can allow for efficient charge transport.

Optionally substitutions for the polymer can include any useful chemical moiety that provides beneficial electronic, chemical, and/or structural properties. Non-limiting moieties include an optionally substituted C₃₋₂₄ alkyl (e.g., including linear, cyclic, or branched alkyl, as well as alkyl optionally having one or more double and/or triple bonds), optionally substituted C₃₋₂₄ thioalkyl (e.g., an optionally substituted —S—R, wherein R is an optionally substituted C₃₋₂₄ alkyl, as described herein), an optionally substituted C₃₋₂₄ haloalkyl (e.g., a C₃₋₂₄ alkyl substituted with one or more halo, such as any described herein), optionally substituted C₃₋₂₄ alkoxy (e.g., an optionally substituted —O—R, wherein R is an optionally substituted C₃₋₂₄ alkyl, as described herein), halo (e.g., fluoro, chloro, bromo, or iodo), as well as combinations thereof. In turn, optional substituents for these moieties include halo (e.g., fluoro, chloro, bromo, or iodo), oxo (═O), or any described herein for alkyl.

In some embodiments, the polymer includes a structure of formula (I):

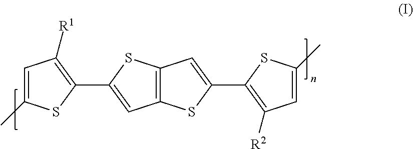

or an ion thereof, wherein each of R¹ and R² is, independently, H, an optionally substituted aliphatic, or cyano; and n is an integer greater than 1 (e.g., from 1 to 1,000; 1 to 10,000; 10 to 1,000; 10 to 10,000; 20 to 1,000; or 20 to 10,000). In particular embodiments, each of R¹ and R² is, independently, an optionally substituted alkyl.

In other embodiments, the polymer includes a structure of formula (II):

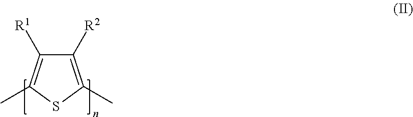

or an ion thereof, wherein each of R¹ and R² is, independently, H, an optionally substituted aliphatic, or cyano, or in which R¹ and R², taken together, with the carbon atom to which each are attached, form a cycloalkyl or a heterocyclyl group, as defined herein; and n is an integer greater than 1 (e.g., from 1 to 1,000; 1 to 10,000; 10 to 1,000; 10 to 10,000; 20 to 1,000; or 20 to 10,000). In particular embodiments, R¹ and R², taken together, is an optionally substituted alkylene or an optionally substituted heteroalkylene. In particular embodiments, each of R¹ and R² is, independently, H or an optionally substituted alkyl.

In yet other embodiments, the polymer includes a structure of formula (III):

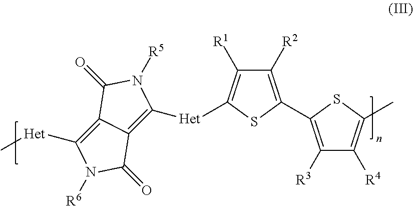

or an ion thereof, wherein each of R¹, R², R³, and R⁴ is, independently, H, an optionally substituted aliphatic, or cyano, or in which R¹ and R², taken together, or R³ and R⁴, taken together, or with the carbon atom to which each are attached, form a cycloalkyl or a heterocyclyl group, as defined herein; each of R⁵ and R⁶ is, independently, H, optionally substituted aliphatic, or optionally substituted aromatic; each of Het is, independently, an optionally substituted heterocyclyl, an optionally substituted aromatic, an optionally substituted aryl, or an optionally substituted heteroaryl; and n is an integer greater than 1 (e.g., from 1 to 1,000; 1 to 10,000; 10 to 1,000; 10 to 10,000; 20 to 1,000; or 20 to 10,000).

In some embodiments, Het is optionally substituted pyridine, optionally substituted pyrazine, optionally substituted pyridazine, optionally substituted pyrimidine, optionally substituted triazine, optionally substituted pyrroline, optionally substituted pyrrole, optionally substituted imidazoline, optionally substituted pyrazole, optionally substituted imidazole, optionally substituted furan, optionally substituted thiophene, optionally substituted oxazole, optionally substituted isoxazole, optionally substituted isothiazole optionally substituted thiazole, optionally substituted pyran, optionally substituted oxazine, optionally substituted thiazine, or optionally substituted quinoxaline. In particular embodiments, the Het is optionally substituted pyrazine.

The polymer can be formed from any useful monomer. Non-limiting monomers can include an optionally substituted thiophene, an optionally substituted thienothiophene, an optionally substituted benzodithiophene, an optionally substituted cyclopentadithiophene, an optionally substituted bithiophene, an optionally substituted quaterthiophene, an optionally substituted isothianaphthene, an optionally substituted ethylenedioxythiophene, as well as combinations thereof. In some embodiments, monomers can include thiophene units, 3-alkylthiophene units, thienothiophene units, pyrrole units, furan units, carbazole units, aniline units, ethylenedioxythiophene units, ethylenedithiolate units, methoxyphenylenvinylene units, dialkoxyphenylenevinylene units, and/or diketopyrrolopyrrole units.

Yet other monomers can include 2,5-thiophenediyl, 5,5′-(2,2′-bithiophenediyl), 2,6-naphthalenediyl, 1,4-phenylenediyl, 1,2-ethylidene, 1,2-ethynylidene, and diketopyrrolopyrrole, as well as similar subunits with the possibility that heteroatoms, such as N or O, of the above listed conjugating subunits could be substituted for S and/or for some of the ring carbons; and/or that side chain substituents could be substituted for some of the hydrogen on the ring, if stability and conjugation are maintained.

Non-limiting polymers include poly(thiophene), poly(alkylthiophene), poly(aniline), poly(acetylene), poly(pyrrole), poly(p-phenylene sulfide), poly(p-phenylene vinylene), poly(indole), poly(pyrene), poly(carbazole), poly(azulene), poly(azepine), poly(fluorene), poly(naphthalene), and poly(diketopyrrolopyrrole), as well as combinations thereof (e.g., as a copolymer)

The molecular weight (MW, e.g., weight average MW) of the polymers can range, for example, from 1,000 Daltons (Da) to 250,000 Da (e.g., from 2,000 Da to 200,000 Da, from 10,000 Da to 150,000 Da, from 20,000 Da to 150,000 Da, or 20,000 Da to 250,000 Da). Polydispersity for the polymers can be 1 or greater, such as from about 1.5 to about 10, or about 1.6 to about 8.

Exemplary, non-limiting polymers also include poly[2,5-bis(3-tetradecylthiophen-2-yl)thieno[3,2,-b]thiophene] (PBTTT-C14); poly[[2,2′-bithiophene]-5,5′-diyl(9,9-dioctyl-9H-fluorene-2,7-diyl)] (F8T2); poly(3,3′″-didodecyl[2,2′:5′,2″:5″,2′″-quaterthiophene]-5,5′″-diyl) (PQT-12); poly(3-octylthiophene-2,5-diyl) (P30T); poly(3-cyclohexylthiophene-2,5-diyl); poly(3-dodecylthiophene-2,5-diyl) (P3DDT); poly(3-butylthiophene-2,5-diyl) (P3BT); poly(3-hexylthiophene-2,5-diyl) (P3HT); poly[2,7-(9,9-dioctylfluorene)-alt-4,7-bis(thiophen-2-yl)benzo-2,1,3-thiadiazole] (PFO-DBT); poly[(5,6-difluoro-2,1,3-benzothiadiazole-4,7-diyl)-alt-(3,3′″-di(2-nonyltridecyl)-2,2′,5′, 2″,5″, 2′″-quaterthiophen-5,5′″-diyl)] (PffBT4T-C9C1); poly[(5,6-difluoro-2,1,3-benzothiadiazol-4,7-diyl)-alt-(3,3′″-di(2-octyldodecyl)-2,2′,5′, 2″,5″, 2′″-quaterthiophen-5,5′″-diyl)] (PffBT4T-2OD); poly[2,6-(4,4-bis-(2-ethylhexyl)-4H-cyclopenta [2,1-b;3,4-b′]dithiophene)-alt-4,7(2,1,3-benzothiadiazole)] (PCPDTBT); poly[[5-(2-ethylhexyl)-5,6-dihydro-4,6-dioxo-4H-thieno[3,4-c]pyrrole-1,3-diyl](4,4′-didodecyl[2,2′-bithiophene]-5,5′-diyl)] (PBTTPD); poly[[4,8-bis[5-(2-ethylhexyl)-2-thienyl]benzo[1,2-b:4,5-b′]dithiophene-2,6-diyl][2-(2-ethyl-1-oxohexyl)thieno[3,4-b]thiophenediyl]] (PBDTTT-C-T); poly[[5-(2-ethylhexyl)-5,6-dihydro-4,6-dioxo-4H-thieno[3,4-c]pyrrole-1,3-diyl][4,8-bis[(2-ethylhexyl)oxy]benzo[1,2-b:4,5-b′]dithiophene-2,6-diyl]] (PBDT-TPD); poly[N-9′-heptadecanyl-2,7-carbazole-alt-5,5-(4′,7′-di-2-thienyl-2′,1′,3′-benzothiadiazole)] (PCDTBT); poly(3,4-ethylenedioxythiophene) (PEDOT); poly[2,6-(4,4-bis-sodium butanylsulfonate-4H-cyclopenta [2,1-b;3,4-b′]dithiophene)-alt-4,7(2,1,3-benzothiadiazole)] (CPE-Na); poly{[N,N′-bis(2-octyldodecyl)-naphthalene-1,4,5,8-bis(dicarboximide)-2,6-diyl]-alt-5,5′-(2,2′-bithiophene)}(P(NDI2OD-T2) or N2200); N-triethylene glycol functionalized version of N2200 (TEG-N2200); N-oligoethylene glycol functionalized version of N2200 (p(gNDI-gT₂)); poly[[7-fluoro-1,2-dihydro-1-(4-octadecyldocosyl)-2-oxo-3H-indol-6-yl-3-ylidene]-(1E)-1,2-ethenediyl[7-fluoro-1,2-dihydro-1-(4-octadecyldocosyl)-2-oxo-3H-indol-6-yl-3-ylidene](2,6-dioxobenzo[1,2-b:4,5-b′]difuran-3,7(2H,6H)-diylidene)] (FBDPPV); poly((E)-3-(5-([8,8′-biindeno[2,1 b]thiophenylidene]-2-yl)thiophen-2-yl)-2,5-bis(2-octyldodecyl)-6(thiophen-2-yl)pyrrolo[3,4-c]pyrrole-1,4(2H,5H)-dione) (P(BTP-DPP)); poly(nickel 1,1,2,2-ethenetetrathiolate) (poly(Ni-ett)); thieno[3,2-b]thiophene-diketopyrrolopyrrole (DPPTT); diketopyrrolopyrrole (DPP), and others, as well as copolymers thereof.

The polymer can be provided as a film (e.g., a thin film). In one embodiment, the film has a thickness of from about 5 nm to about 1,000 nm (e.g., of from about 5 nm to 50 nm, 5 nm to 100 nm, 5 nm to 200 nm, 5 nm to 500 nm, 5 nm to 750 nm, 10 nm to 50 nm, 10 nm to 100 nm, 10 nm to 200 nm, 10 nm to 500 nm, 10 nm to 750 nm, 10 nm to 1,000 nm, 20 nm to 50 nm, 20 nm to 100 nm, 20 nm to 200 nm, 20 nm to 500 nm, 20 nm to 750 nm, or 20 nm to 1,000 nm).

### Molecular Dopants

Molecular dopants can be used with any polymer described herein. Whereas use of an organic polymer as the host can employ solution processing, molecular doping can employ vapor deposition processing. In this way, fabrication of FGMs can be simplified and controlled by using low temperature solution processing of the polymer with vapor-based patterning of the dopant.

The FGM herein can include any useful molecular dopant dispersed within the polymer. Non-limiting dopants include p-type dopants and n-type dopants. In some embodiments, the dopant includes an optionally substituted quinodimethane, an optionally substituted naphthoquinodimethane, an optionally substituted perylene, an optionally substituted hexaazatriphenylene, an optionally substituted amine, an optionally substituted ammonium cation, an optionally substituted benzimidazolyl amine, an optionally substituted amino ethylene, and others. Such chemical moieties can include optional substituents, such as halo (e.g., fluoro, chloro, bromo, or iodo), cyano, ester, or a combination thereof, as well as any described herein for alkyl. Any of the dopants herein can be provided in neutral or charged forms (e.g., as ions, such as in cationic forms or anionic forms).

In some embodiments, the dopant includes a structure of formula (IV):

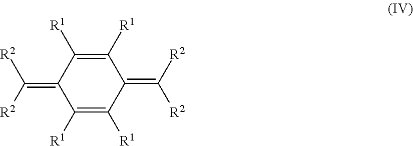

or an ion thereof, wherein each R¹ is, independently, H, halo, or cyano; and each R² is, independently, cyano or optionally substituted ester.

Exemplary, non-limiting dopants include 2,3,5,6-tetrafluoro-7,7,8,8-tetracyano quinodimethane (F4TCNQ); 2,5-difluoro-7,7,8,8-tetracyanoquinodimethane (F2TCNQ); 7,7,8,8-tetracyanoquinodimethane (TCNQ); tetrachloro-1,4-benzoquinone (DDQ), 11,11,12,12-tetracyanonaphtho-2,6-quinodimethane (TCNNQ or TNAP); 1,3,4,5,7,8-hexafluoro-11,11,12,12-tetracyanonaphtho-2,6-quinodimethane (F6TNAP); 2-(3-(adamantan-1-yl)propyl)-3,5,6-trifluoro-7,7,8,8-tetracyanoquinodimethane (F3TCNQ-Ad1); 1,4,5,8,9,11-hexaazatriphenylene hexacarbonitrile (HAT-CN); hexacyano-trimethylene-cyclopropane (CN6-CP); 1,3-bis(N-carbazolyl)benzene (mCP); 1,4-bis(diphenylamino)benzene; 2,6-bis(9H-carbazol-9-yl)pyridine; 4,4′-bis(N-carbazolyl)-1,1′-biphenyl; N,N′-bis(3-methylphenyl)-N,N′-diphenylbenzidine; N,N′-di(1-naphthyl)-N,N′-diphenyl-(1,1′-biphenyl)-4,4′-diamine; molybdenum tris(1,2-bis(trifluoromethyl)ethane-1,2-dithiolene) (Mo(tfd)₃); tris(pentafluorophenyl)borane (B(C₆F₅)₃); and others.

In other embodiments, the dopant includes a structure of formula (V):

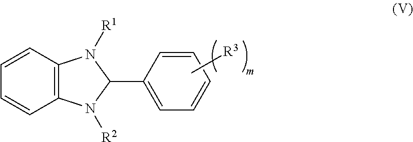

or an ion thereof, wherein each of R¹ and R² is, independently, H, optionally substituted aliphatic, or optionally substituted aromatic; each R³ is, independently, optionally substituted amino, optionally substituted heteraliphatic, or optionally substituted aryloxy; and m is an integer of 0 to 5. In some embodiments, R³ is —NR^{N3}R^{N4} in which each of R^{N3} and R^{N4} is, independently, optionally substituted alkyl (e.g., in with R³ is in the para position). In some embodiments, each of R¹ and R² is, independently, optionally substituted alkyl. In other embodiments, each R³ is, independently, optionally substituted alkoxy or optionally substituted aryloxy. In yet other embodiments, R³ is —OAk, in which Ak is an optionally substituted alkyl (e.g., in which m is 1, 2, or 3; and/or in which R³ is in the ortho and/or para position).

Yet other non-limiting dopants include 4-(2,3-dihydro-1,3-dimethyl-1H-benzimidazol-2-yl)-N,N-dimethylbenzenamine (N-DMBI); 4-(1,3-dimethyl-2,3-dihydro-1H-benzoimidazol-2-yl)-N,N-diphenylaniline (N-DPBI); tetra-n-butylammonium fluoride (TBAF); tetrakis(dimethylamino)ethylene (TDAE); hydrazine; polyethylenimine (e.g., CH₃[NHCH₂CH₂]ₙOH); 4-dodecylbenzenesulfonic acid (DBSA); 4-ethylbenzene sulfonic acid (EBSA); camphorsulfonic acid (CSA); tridecafluoro-1,1,2,2-tetrahydrooctyl)trichlorosilane (FTS); mesitylene pentamethylcyclopentadienyl ruthenium dimer ([RuCp*(mes)]₂); and others.

### Additives and Components

The materials herein can include one or more further additives or components. Non-limiting additives include nanowires, nanotubes (e.g., single walled or multiwalled nanotubes), particles, nanoparticles, binders (e.g., a polymeric binder, such as poly(vinyl alcohol) (PVA)), fillers (e.g., a conductive filler, such as carbon nanotubes, nanowires, or graphene), insulators (e.g., an insulating polymer, such as polyamide (PA), polycarbonate (PC), polyethylene (PE), polypropylene (PP), polystyrene (PS), polyimide (PI), PVA, polyvinyl chloride (PVC), poly(methyl methacrylate) (PMMA), and the like), ions, plasticizers (e.g., dioctyl phthalate), heat stabilizers (e.g., organo-tin compounds), antioxidants (e.g., phenols or amines), and/or UV stabilizers (e.g., benzophenones or salicylates), silicon, glass, and combinations thereof.

Materials having one or more optional additives or components can be of any form, such as a film, a nanocomposite, a nanolaminate, and the like. The materials herein can be disposed upon a substrate or between two substrates. Non-limiting substrates can include a plate, a textile, a foil, a ceramic, a glass, a polymer, a plastic, and the like, as well as reinforced layers or matrices thereof.

### Devices

The materials herein can be employed in any useful device. In one embodiment, the material is employed in a thermoelectric device (e.g., a thermoelectric generator or a Peltier cooler), a temperature control device such as a cooling device, a cooler (e.g., a Peltier cooler), a thermal management device (e.g., for use with a battery), a device for converting waste heat to electricity, or a thermoelectric fabric (e.g., for use in medical cooling devices or seat coolers).

In some embodiments, the thermoelectric device interconverts heat and electrical energy. The materials herein (e.g., any functionally graded thermoelectric material herein) can be employed as a component of a device to capture heat and/or control local temperature.

The efficiency of an FGM or a thermoelectric device can be characterized by its figure of merit, ZT, defined as ZT=α²σT/K, where a is the Seebeck coefficient (or thermopower) [V K⁻¹], a is the electronic conductivity [S m⁻¹], K is the thermal conductivity [W m⁻¹ K⁻¹], and T is the temperature [K]. In principle, the magnitude of a increases as a function of carrier concentration n [m⁻³]. In contrast, the magnitude of a generally decreases with n.

Typically, the performance of devices can be improved by enhancing the material's ZT Along with material optimization, the use of FGMs can offer further improvement in device performance. In principle and without being limited by mechanism, functionally grading motifs with spatial variation in the thermoelectric properties could enable more efficient distribution of heat when operating within a thermoelectric device (e.g., such as a Peltier cooler). In some instance, such efficiency could, in turn, lead to larger cooling temperature gradients and coefficient of performance (C.O.P.). Accordingly, the disclosure herein includes use of a FGM in a device with improved cooling properties (e.g., as compared to a homogenous, uniform material).

Furthermore, the FGM can employ organic conducting polymers that allow for low temperature thermal processing, as compared to inorganic materials. In particular embodiments, such FGMs including polymeric materials can be used in thermoelectric cooling applications (e.g., medical cooling devices, seat coolers, and thermal management for batteries), in which the operating temperatures amenable to these materials (e.g., about 60° C. to about 0° C.) can be most promising.

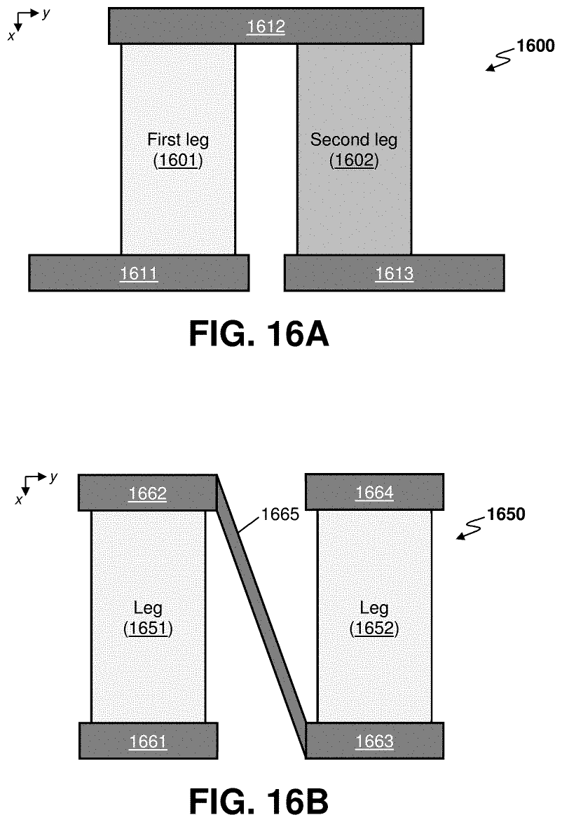

FIG. 16A-16B provides schematics of non-limiting thermoelectric devices. The device can include an FGM material (e.g., any described herein) disposed between two interconnects. The interconnect can be a contact formed from any conductive material (e.g., a metal, such as silver, gold, copper, nickel, and alloys thereof). In one embodiment, the device 1600 can include a dual leg element, in which a first leg 1601 is electrically connected to a first interconnect 1611 and a second interconnect 1612, and in which a second leg 1602 is electrically connected to the second interconnect 1612 and a third interconnect 1613. A plurality of such legs can be provided within the device, in which the legs can be connected thermally in parallel and electrically in series.

The leg can extend between a temperature gradient (e.g., a temperature gradient along the x-axis), in which the continuous gradient of the dopant can also extend along the x-axis. In particular embodiments, the first leg 1601 includes a p-type material (e.g., including a p-type dopant) and the second leg 1602 includes an n-type material (e.g., including a n-type dopant). In other embodiments, the p-type material includes a first organic conducting polymer having a p-type dopant, and the n-type material includes a second organic conducting polymer having an n-type dopant. The first and second organic conducting polymers can be the same or different.

In another embodiment, as seen in FIG. 16B, the device 1650 can include a uni-leg element, in which a first leg 1651 is electrically connected to a first interconnect 1661 and a second interconnect 1662. A plurality of such legs can be provided within the device. As can be seen, the device 1650 can include a second leg 1652 that is electrically connected to a third interconnect 1663 and a fourth interconnect 1664 with a conductive bridge 1665 disposed between the second and third interconnects 1662, 1663.

One or more of the legs can be formed from an FGM, such as any described herein. In one embodiment, the first and second legs are formed from dissimilar materials with different Seebeck coefficients. In another embodiment, the leg(s) extend between a temperature gradient (e.g., a temperature gradient along the x-axis), in which the continuous gradient of the dopant can also extend along the x-axis.

The legs can extend in any direction. In one embodiment, the legs can extend vertically between a top surface and a bottom surface, in which the top surface is exposed a heat source, and the bottom surface is exposed to a heat sink. In another embodiment, the top surface is exposed a heat sink, and the bottom surface is exposed to a heat source. In this way, heat flows vertically along the thermoelement arms and between the substrates forming the top and bottom surfaces. In other embodiments, the legs can extend horizontally and in plane to the top and bottom surfaces. Such planar or lateral arrangements can be printed or deposited on a substrate. Substrates that provide the top and bottom surfaces can include any material, such as a flexible substrate, a foil, a plate, or others described herein.

The device can be characterized as having a parallel plate configuration (e.g., in which the legs extend in the vertical direction, the interconnects are arrayed in a top horizontal plane and a bottom horizontal plane, and the temperature field extends in the vertical direction across the top and bottom horizontal planes) or a thin-film in-plane configuration (e.g., in which the legs extend in the horizontal plane, the interconnects are arrayed in the same horizontal plane as the legs, and the temperature field extends in the horizontal direction between a first edge and a second edge of the horizontal plane). In particular embodiments, the device is characterized as a thin film device allowing for flexible and/or conformal modules.

### EXAMPLES

### Example 1: Continuously Graded Semiconducting Polymers Enhance Thermoelectric Cooling

Molecularly doped semiconducting polymers have demonstrated great potential in organic thermoelectrics (TEs) for thermal energy management. While functionally graded materials (FGMs) where one spatially controls and optimizes transport properties across the length of a TE leg can improve TE device performance in inorganic materials, experimentally fabricating FGMs has been a challenging task.

Described herein, we utilize the facile processability and ability to modulate electronic properties through molecular doping of conjugated polymers to fabricate and characterize thin films of organic FGMs. Here, we leverage sequential vapor doping of poly[2,5-bis(3-tetradecylthiophen-2-yl) thieno [3,2-b]thiophene] (PBTTT) with the small molecule acceptor 2,3,5,6-tetrafluoro-7,7,8,8-tetracyanoquinodimethane (F4TCNQ) to fabricate a form of FGMs, e.g., continuously graded thin films, through a special-designed vapor doping apparatus.

Here, we provide understanding of the charge transport properties (e.g., Seebeck coefficient α and electrical conductivity σ), structural properties, and cooling performance along the continuous gradient. The spatial distribution of σ was measured through an array of microfabricated electrodes to reveal the presence of the gradient. By using grazing incidence wide angle x-ray scattering (GIWAXS), we characterized the local order and the lateral spatial distribution of the dopant across the film to confirm the compositional gradient and yield the width of the gradient. In some instances, we observed the presence of a gradient of about 4 mm across, in which the doping level and transport properties varied continuously. Furthermore, we observed a gradual change in both side-chain stacking and π-π stacking distances across the graded film.

Using a 1D thermoelectric coupling model, we predicted TE cooling performances based on the experimental transport properties of continuously graded (CG) thin films. Cooling temperature (ΔT) and coefficient of performance (C.O.P.) were calculated through linear constitutive relations coupled with conservation of charge and energy. The results demonstrated that ΔT of CG samples were significantly improved, compared to that of a sample having a uniform profile (uniform doping of the polymer). Such results can, for instance, provide a simple yet powerful method to enhance thermoelectric performance of molecularly doped organic semiconductors for providing more efficient organic thermoelectric devices. Additional details follow.

### Example 2: Fabricating Continuously Graded Films Through Sequential Vapor Doping

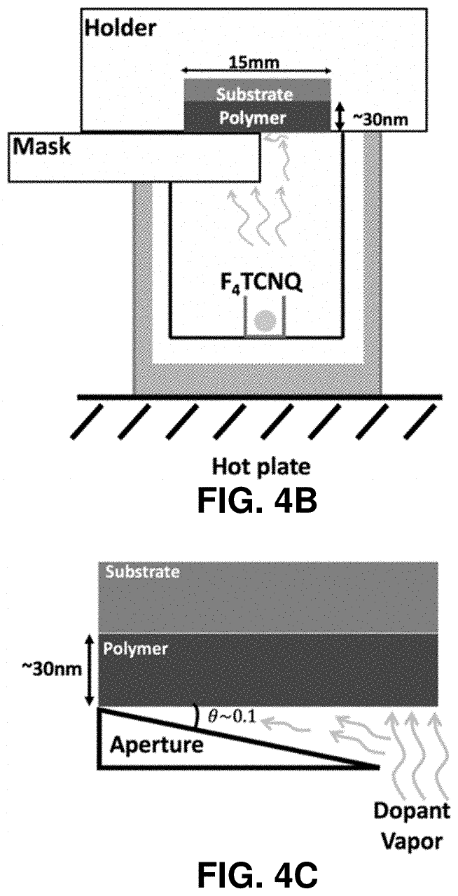

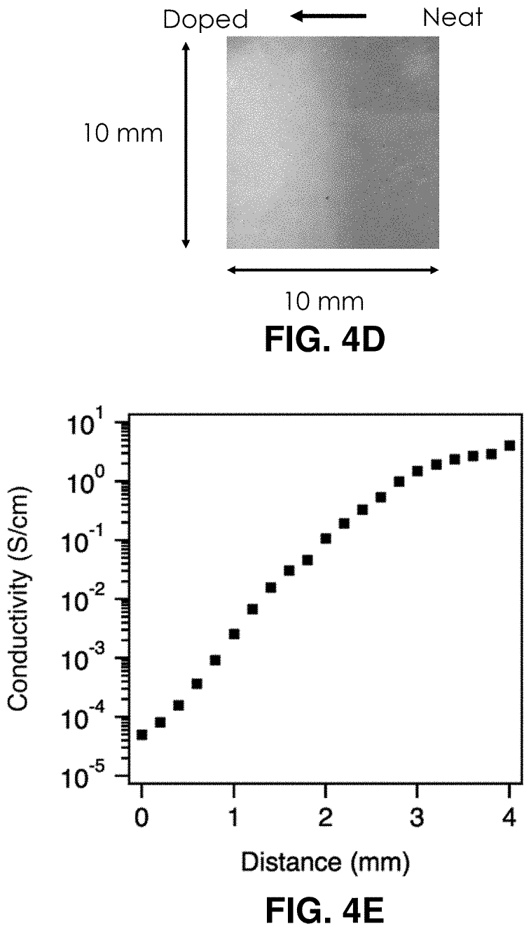

Continuously graded polymer thin films (e.g., samples that have an in-plane gradient of level in molecular doping across the whole film) were fabricated through a sequential vapor doping process. The polymer-dopant system in this Example included PBTTT:F4TCNQ, whose chemical structures are shown in FIG. 4A. In the vapor doping process, the neat polymer films were spun cast prior to the addition of dopant. This process largely preserves the morphology of the polymer thin film, resulting in a much higher electrical conductivity compared to films made through solution doping process. To achieve graded films, we employed a sequential vapor doping method to easily vary the doping levels across the film. This FGM fabrication method was superior to solution doping process or inorganic processing, which requires making solutions with new compositions.

In FIG. 4B-4C, we show a schematic of our home-built system for controlled vapor doping of polymer thin films in an inert atmosphere (e.g., argon atmosphere glovebox). We used a cover mask having a concave surface (FIG. 4C), which leaves a gap between the polymer surface and the mask. This gap can allow dopant vapor diffusion during the doping process, which will be proven later to form a gradient in doping level after establishing the film. Using this method, we were able to fabricate a non-limiting FGM, in which the doping level gradient gradually increasing from neat to doped. FIG. 4D shows a non-limiting doped film. However, it is worth nothing that we were also able to fabricate other continuously graded patterns in terms of compositional control of dopant, as we could vary the vapor doping time on each side of the film to achieve different doping level gradients.

The spatial distribution of a was characterized through arrays of interdigitated electrodes (IDEs) across the neat to doped graded film to confirm the presence of a continuous gradient. There were in total 30 IDEs; and each IDE measured a 100 μm by 300 μm region and was laterally spaced apart by 200 μm. The detailed IDE fabrication process is described herein in Example 6. The spatial conductivity profile of a non-limiting CG PBTTT film is shown in FIG. 4E. This spatial distribution revealed the presence of a gradual gradient, in which conductivity increased from the neat side to the doped side of the film and the width of the gradient was about 4 mm.

Although IDE measurements allowed us to characterize the spatial gradient with a fine resolution (e.g., about 200 μm), the maximum conductivity measured by IDEs was approximately an order of magnitude lower than the actual conductivity value due to the influence of contact resistance in IDE measurements, which is especially pronounced at high conductivity range. Therefore, we also applied a four-point probe technique to accurately map out the conductivity profiles, as discussed herein in Example 4.

### Example 3: Influence of Molecular Doping on Local Structure and Dopant Distribution

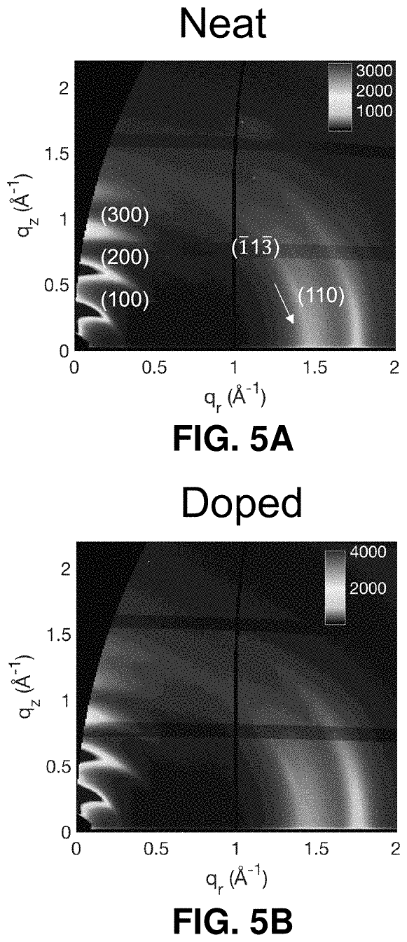

In addition to IDE measurements, we also probed the dopant distribution across the film and determined the local order of the polymer chains upon doping by performing grazing incidence wide angle X-ray scattering (GIWAXS) experiments. The GIWAXS images of neat PBTTT thin film conveyed the characteristic scattering pattern for as-cast PBTTT (see, e.g., a representative image of a neat film in FIG. 5A). The GIWAXS image indicated side-chain stacking (h00) peaks up to the 4th order in the out-of-plane direction along with the backbone reflection (1̅13̅), as well as the reflection (110) related to the π-π stacking in the in-plane direction. This observation indicates a preferential edge-on orientation of polymer crystallites, resulting from the casting conditions employed for these films.

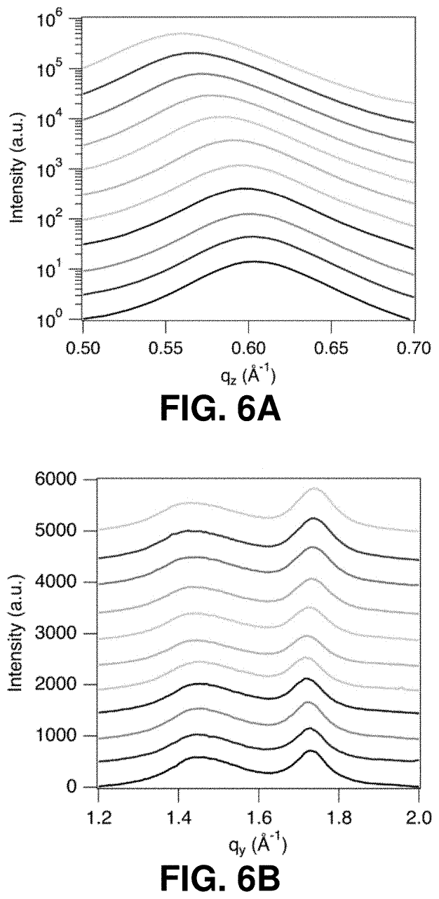

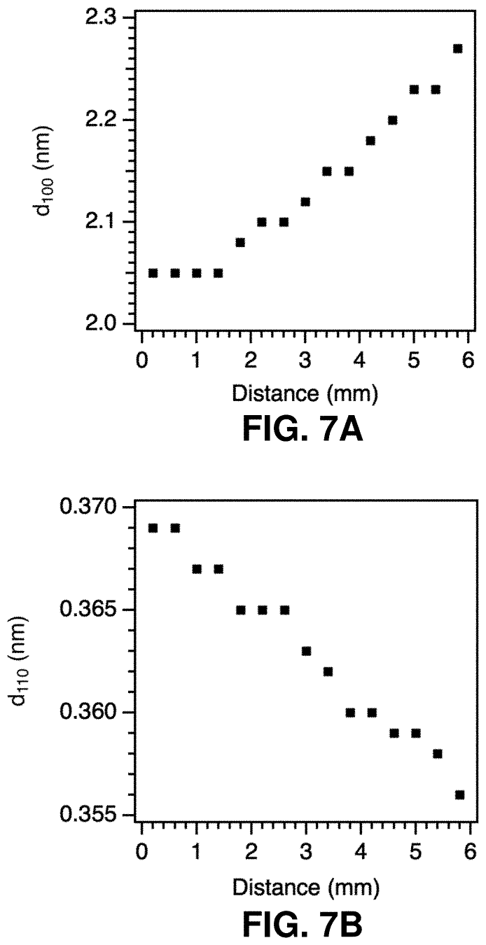

A representative GIWAXS image of PBTTT:F4TCNQ graded films is shown in FIG. 5B. The overall scattering patterns of doped sides were qualitatively similar to neat PBTTT, which indicates that vapor infiltration with F4TCNQ largely preserves the semicrystalline morphology of PBTTT and is consistent with previous reports. By taking linecuts along both out-of-plane and in-plane directions (FIG. 6A-6B), we observed quantitative changes through side-chain stacking and π-π stacking distance moving from neat side of the film to the doped side. Starting from neat side, the first order side-chain spacing d₁₀₀ was 2.05 nm, and this value was maintained within the first 2 mm (FIG. 7A). Then, we observed a gradual increase in the side-chain spacing distance to 2.27 nm over a total 4 mm distance until reaching a plateau at the doped side of the film (FIG. 7A). As shown in FIG. 7B, the spatial distribution for π-π stacking distance showed a similar trend, but inversely correlated. Both profiles of side chain and π-π stacking spacing indicated a gradient in dopant distribution of about 4 mm, which correlates well with the gradient profile as observed in IDE conductivity measurements.

Whereas a gradient can be maintained within the plane of the film (e.g., along the x-y plane), the dopant concentration within the thickness of the film can be generally uniform. The uniformity of the dopant concentration can be determined in any useful manner, such as by use of GIWAXS experiments as a function of angle of incidence to determine the dopant composition through the thickness of the film (in an out-of-plane direction).

### Example 4: Determination of Macroscopic Seebeck Coefficient and Conductivity Profiles

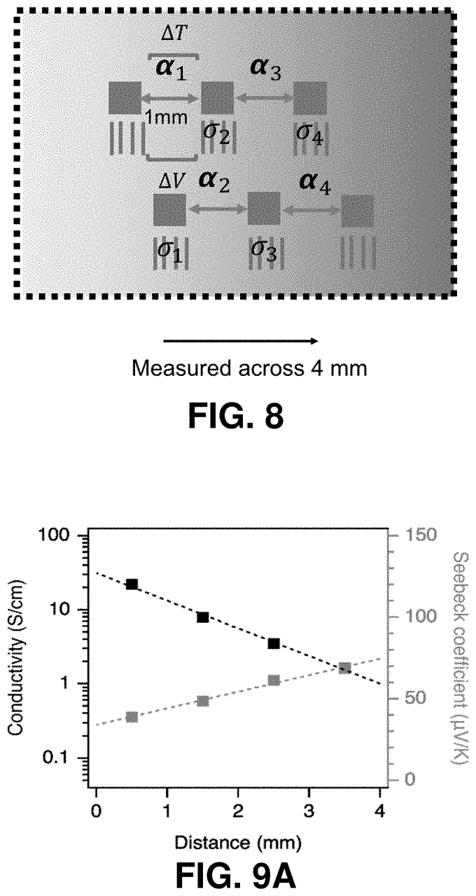

Here, we present and discuss the results for the measured macroscopic σ and α values across the 4 mm gradient of the CG films. FIG. 8 shows the geometry and arrangement of the gold contacts used for obtaining the conductivity and Seebeck coefficient measurements described herein. The detailed set up and contact geometry can be found in Example 6 herein. Measurements were taken each 1 mm apart to ensure sufficient voltage response. Both conductivity and Seebeck coefficient were spatially measured at four spots along the gradient.

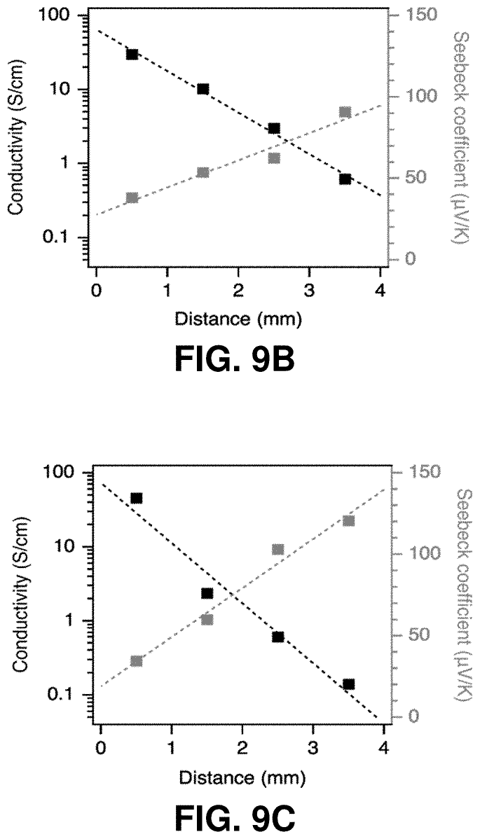

In order to investigate how different gradient profiles affect the device cooling performance, we fabricated three continuously graded samples with different magnitudes in the slope of both σ and α by controlling vapor doping time in our fabrication process. FIG. 9A-9C summarizes σ and α profiles across three continuously graded samples. Table 1 and Table 2 provide σ and α for the three samples.

TABLE 1
Seebeck coefficient data across the continuously graded polymer films

| | α₁ (μV/K) | α₂ (μV/K) | α₃ (μV/K) | α₄ (μV/K) | |
|---|---|---|---|---|---|
| Sample | (x = 0.5 mm) | (x = 1.5 mm) | (x = 2.5 mm) | (x = 3.5 mm) | α_{avg} |
| G1 | 38.9 | 48.7 | 61.4 | 68.5 | 54.4 |
| G2 | 37.9 | 53.5 | 62.5 | 90.8 | 61.2 |
| G3 | 34.4 | 59.9 | 103.0 | 120.4 | 79.4 |

TABLE 2
Conductivity data across the continuously graded polymer films

| | σ₁ (S/cm) | σ₂ (S/cm) | σ₃ (S/cm) | σ₄ (S/cm) | |
|---|---|---|---|---|---|
| Sample | (x = 0.5 mm) | (x = 1.5 mm) | (x = 2.5 mm) | (x = 3.5 mm) | σ_{avg} |
| G1 | 22.0 | 7.91 | 3.51 | 1.64 | 3.75 |
| G2 | 29.9 | 10.2 | 3.00 | 0.610 | 1.90 |
| G3 | 45.3 | 2.35 | 0.600 | 0.140 | 0.432 |

The spatial averages of α and σ were determined as follows:

$${α}_{a v g} = ( {α}_{1} + {α}_{2} + {α}_{3} + {α}_{4} ) / 4 and$$

$$\frac{1}{{σ}_{avg}} = ( \frac{1}{{σ}_{1}} + \frac{1}{{σ}_{2}} + \frac{1}{{σ}_{3}} + \frac{1}{{σ}_{4}} ) / 4.$$

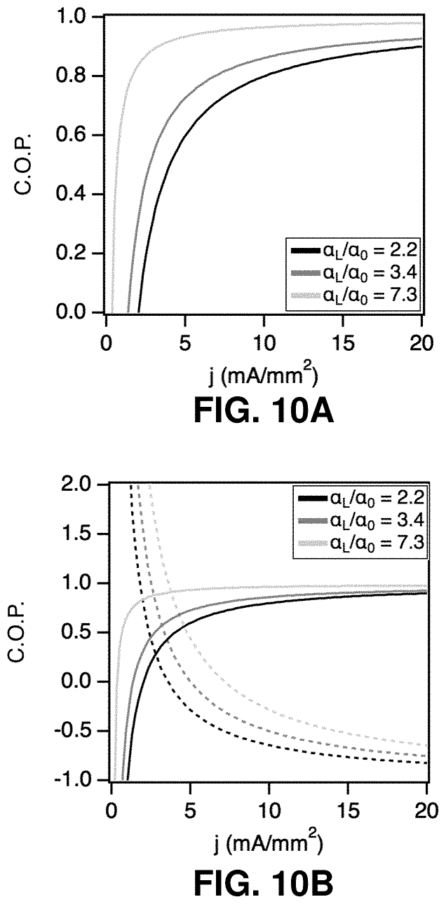

For all three samples, the Seebeck coefficient profiles followed a linear trend, whereas the conductivity profiles follow an exponential trend (note the log-scale of the conductivity axis). A parameter that defined the magnitude of the gradient is the ratio of Seebeck coefficient/conductivity between one end of the gradient to the other. As expected, the Seebeck coefficient decreased with increasing conductivity. As shown in FIG. 10A-10B, Seebeck ratios were 2.2, 3.4 and 7.3; and the corresponding conductivity ratios were 3×10⁻², 6×10⁻³, and 6×10⁻⁴, respectively.

### Example 5: Prediction of Cooling Performance for Continuously Graded Films

Based on the measured conductivity and Seebeck coefficient profiles, we predicted the cooling performance of a continuously graded film within a single p-type leg in a Peltier cooler. The (thermoelectric) Peltier effects discussed herein are based on a linear Onsager theory. Under isotropic conditions, the constitutive relations are as follows:

j=σE−σα∇T Equation (1) and

q=αTj−κ∇T Equation (2),

where j is the current density, σ is the electrical conductivity, E is the electrical field, α is the Seebeck coefficient, T is the temperature, q is the heat flux, κ is the thermal conductivity, and ∇ is the nabla operator.

Assuming steady-state conditions, the principles of conservation of charge and energy are as follows:

∇·j=0 Equation (3) and

∇·q=j·E Equation (4), respectively.

We fixed the hot side temperature at 300 K, and considered the case of one dimensional (1D) transport. We also assumed that thermal conductivity was uniform throughout the device. The Seebeck profile increased linearly and electrical conductivity decreased exponentially (linearly on the semi-log scale), based on our experimental results. By coupling the equations for heat (Equation 2) and charge transport (Equation 1), we solved for the 1D temperature profile across our film as follows:

$$- κ \frac{{\partial }^{2} T ( x )}{\partial {x}^{2}} = \frac{{j}^{2}}{σ ( x )} - j \frac{d α ( x )}{dx} T ( x ) . \qquad Equation ( 5 )$$

The term on the left-hand side of the equation

$$( κ \frac{{\partial }^{2} T ( x )}{\partial {x}^{2}} )$$

refers to thermal conduction, the first term on the right-hand side

$$( \frac{{j}^{2}}{σ ( x )} )$$

refers to joule heating, and the second term on the right-hand side

$$( j \frac{d α ( x )}{dx} T ( x ) )$$

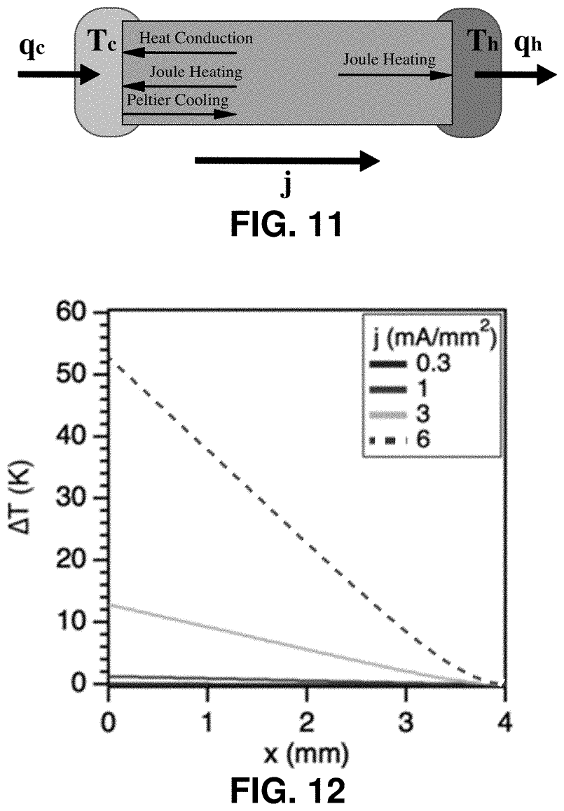

refers to the Peltier cooling effect. To arrive at Equation (5), we considered FIG. 11, which provides a schematic of the contribution of various heat elements in a Peltier cooler.

As seen in FIG. 11, there are three components to the heat flux at the cold side Q_{c}: the Peltier effect Qₚ, joule heating Q_{J}, and heat conduction Q_{K}. The Peltier effect Qₚ removes heat from the cold side T_{C}. Joule heating Q_{J} uniformly heats the device, so half of the heat generated goes to the cold side. Heat conduction Q_{K} moves heat from the hot side Tₕ to the cold side T_{c}. These result in the following equations:

$${Q}_{c} = {Q}_{P} + {Q}_{J} + {Q}_{Κ}$$

$${Q}_{c} = I α {T}_{C} - \frac{1}{2} {I}^{2} R - K Δ T$$

$$\frac{Q}{A} = q = \frac{I}{A} α {T}_{C} - \frac{1}{2} \frac{{I}^{2}}{A} R - \frac{κ A}{l A} Δ T$$

$$q = j α {T}_{C} - \frac{1}{2} jIR - \frac{κ}{l} Δ T$$

$$q = j α {T}_{C} - \frac{1}{2} jI \frac{l}{σ A} - \frac{κ}{l} Δ T$$

$$q = j α {T}_{C} - \frac{1}{2} {j}^{2} \frac{l}{σ} - κ \frac{Δ T}{l}$$

If we have a functionally graded device, then q_{c} can be characterized a function of x. This is because the material properties of the device change along a length l of the FGM. In this paradigm, the segment length l goes to 0, so the limit of the equation below can be determined as l goes to 0:

$${lim}_{l \to 0} q = j α {T}_{C} - \frac{1}{2} {j}^{2} \frac{( 0 )}{σ} - κ \frac{d T}{d l} \\ q ( x ) = j α {T}_{C} - κ ∇ T$$

This provides q_{c} as a function of x. As can be seen, the joule heating term disappears. Without wishing to be limited by mechanism, this phenomenon can be contributed to the improved performance of FGMs. While this assumption is consistent with work that investigate the performance of continuously graded devices, further work can explore the accuracy of this assumption, and we can still expect a functionally graded device to minimize the effects of joule heating.

We then solved for the temperature of the gradient for a continuously graded device. By combining Equations (1)-(4), we obtained the following:

$$∇ \cdot \vec{q} = \vec{j} \cdot \vec{E}$$

$$∇ \cdot \vec{q} = \vec{j} \cdot ( \frac{\vec{j}}{σ} + α ∇ T )$$

$$∇ \cdot ( α T \vec{j} - κ ∇ T ) = \vec{j} \cdot ( \frac{\vec{j}}{σ} + α ∇ T )$$

$$\frac{d}{dx} ( α Tj - κ \frac{dT}{dx} ) = \frac{{j}^{2}}{σ} + j α \frac{dT}{dx}$$

$$j \frac{d ( α T )}{dx} - κ \frac{{d}^{2} T}{{dx}^{2}} = \frac{{j}^{2}}{σ} + j α \frac{dT}{dx}$$

$$j ( \frac{d α}{dx} T + α \frac{dT}{dx} ) - κ \frac{{d}^{2} T}{{dx}^{2}} = \frac{{j}^{2}}{σ} + j α \frac{dT}{dx}$$

$$j \frac{d α}{dx} T - κ \frac{{d}^{2} T}{{dx}^{2}} = \frac{{j}^{2}}{σ}$$

Rearranging then provides:

$$κ \frac{{d}^{2} T}{d {x}^{2}} = j \frac{d α}{d x} T ( x ) - \frac{{j}^{2}}{σ ( x )}$$

Numerical integration of Equation 5 was conducted with Python to obtain the solution of temperature across the film, T(x). The temperature profile decreased more dramatically when higher current density j was applied (FIG. 12). This phenomenon can be understood by considering that the higher the current density, the more electrical work being done by the device, and therefore a stronger Peltier cooling effect to be observed.

In order to obtain rational and reasonable current density for cooling temperature calculations, i.e. the device has non-negative efficiency, we also looked into the coefficient of performance (C.O.P.) of the graded samples. C.O.P. is a metric to determine device efficiency and can be defined as the cooling power (absorbed heat per time per cross-sectional area) divided by the net power output density (electrical power output per cross-sectional area):

$$C . O . P . = \frac{{[ α ( x ) T ( x ) j - κ \frac{\partial T ( x )}{\partial x} ]}_{x = 0}}{{\int }_{0}^{L} [ α ( x ) j \frac{\partial T ( x )}{\partial x} + \frac{{j}^{2}}{σ ( x )} ] dx} , \qquad Equation ( 6 )$$

where L is the length of the device.

C.O.P. values for three graded samples were plotted against current density input j in FIG. 10A-10B. All graded samples shared a similar shape of the C.O.P. curve. The sample with steepest Seebeck coefficient and conductivity slopes had the highest device efficiency. In addition, the spatial averages of conductivity and Seebeck coefficient of each graded samples were used to calculate the C.O.P. of the uniform equivalents. It is worthwhile noting that devices with uniform material properties do not exhibit the same peaked behavior in C.O.P. that is observed in continuously graded devices (FIG. 10B). The C.O.P. of a device with uniform properties was calculated as follows:

$$C . O . P . = \frac{α {T}_{C} j - \frac{1}{2} {j}^{2} \frac{L}{σ} - κ \frac{Δ T}{L}}{α j Δ T + {j}^{2} \frac{L}{σ}} . \qquad Equation ( 7 )$$

The joule heating term

$$( \frac{1}{2} {j}^{2} \frac{L}{σ} )$$

increases more rapidly than the Peltier effect term (αT_{C}j), which will eventually lead to a negative C.O.P value. In practice, this means that the electrical current is producing more heat than that being shifted by the Peltier effect, resulting in heating of the device. Without wishing to be limited by mechanism, the difference in C.O.P. behavior between the uniform and functionally graded devices illustrates a possible advantage of the functionally graded devices, i.e., the distributed joule heating of the FGM device leads to a maximum efficiency at higher current densities.

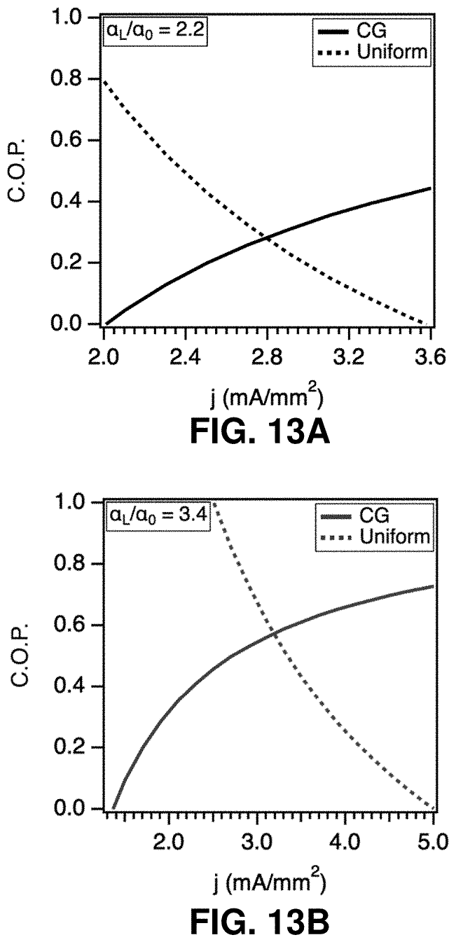

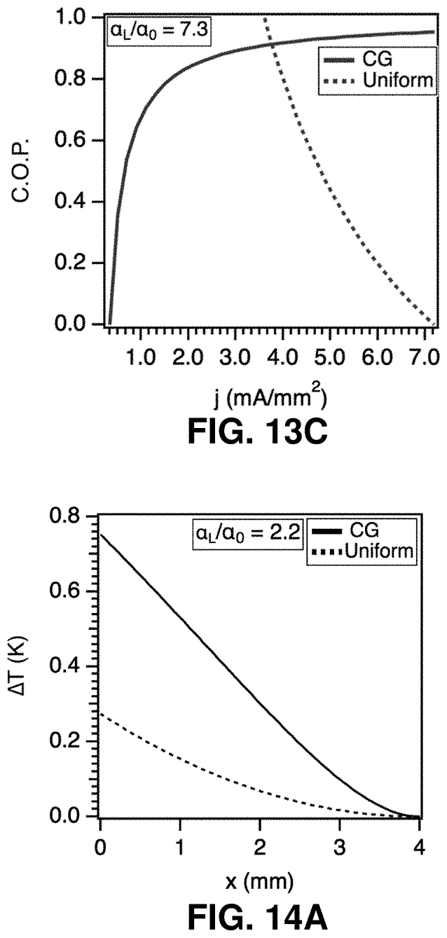

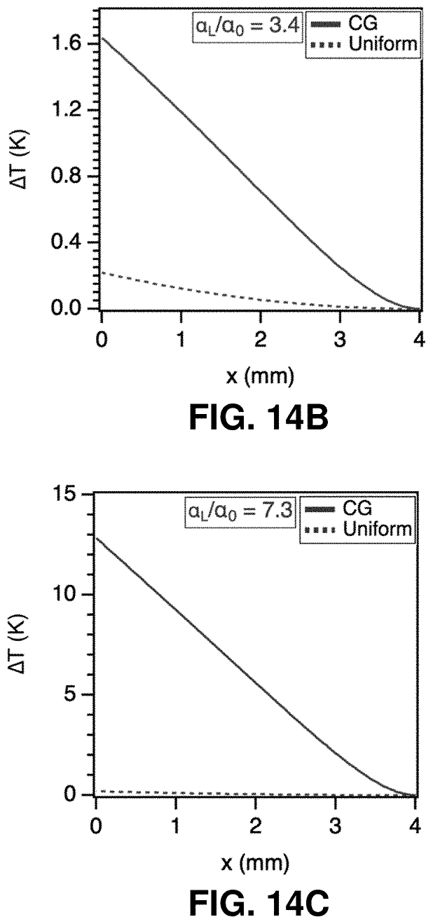

As shown in FIG. 10B, the curves of graded films and their uniform equivalents yielded the current density ranges for each film to provide a non-negative C.O.P. Specifically, j lies in ranges of [2.0, 3.6], [1.4, 5.0] and [0.3, 7.2] mA/mm² for three samples, respectively (FIG. 13A-13C). Following the yielded ranges, we choose 3 mA/mm² as our input current density for the following cooling temperature calculations because this value produced positive C.O.P. values for all three CG films and uniform equivalents. Calculated T(x) profiles of continuously graded samples are shown in FIG. 14A-14C. The cooling temperature ΔT was calculated as the difference between the temperature at the hot side (T_{H}=300 K) and the temperature at the cold side (T_{C}=T (x=0)). In addition, the temperature profiles of the equivalent uniform film for each graded sample were plotted to compare with that of the graded samples (FIG. 14A-14C).

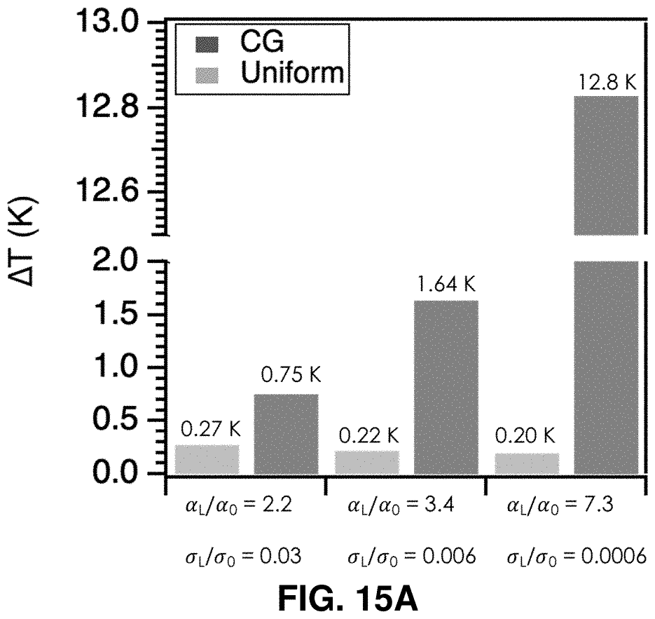

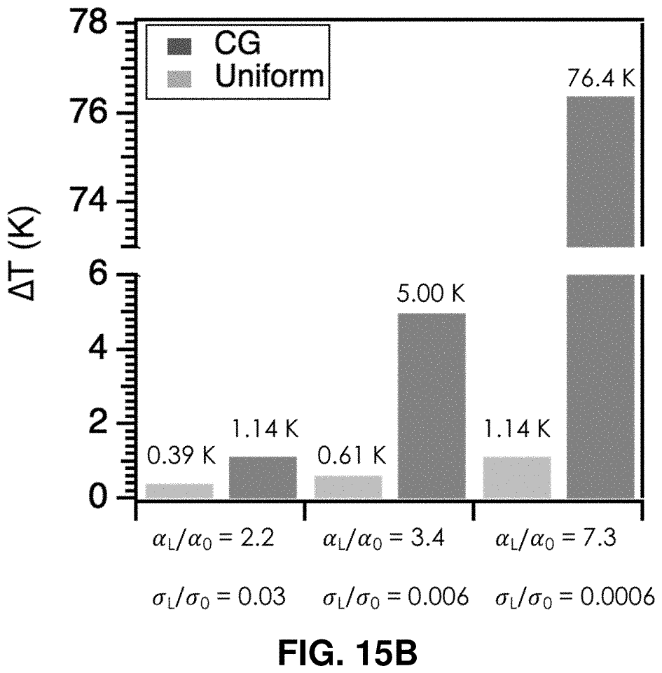

Cooling temperatures were calculated for all three samples and their uniform equivalents at a constant input current density of 3 mA/mm² (FIG. 15A). The ΔT values of continuously graded samples were 0.75 K, 1.64 K, and 12.8 K, respectively. As shown clearly in the bar graph, all graded samples had larger ΔT values than that of their uniform equivalents, which in turn proves that FGMs improve the Peltier cooling performance. In addition, the values of ΔT were calculated for all graded samples at their local optimal current densities, which were 1.14 K, 5.00 K and 76.4 K, respectively (FIG. 15B).

It is worth noting that cooling temperature generally increased more than an order of magnitude among graded samples, while their uniform equivalents had approximately the same cooling performance (˜0.25 K). Especially, ΔT of the graded sample with the steepest Seebeck ratio (α_{L}/α₀=7.3) was more than 60 times greater than its uniform equivalent. Without wishing to be limited by mechanism, we assigned this improvement in ΔT to the increase in Seebeck coefficient along with the decrease in conductivity. As seen in Equation (5), the cooling temperature T(x) is strongly dependent on α(x) and σ(x) profiles, specifically the absolute value of σ(x) and the first derivatives of α(x), i.e., dα(x)/dx. In one example, the Seebeck coefficient profiles followed a linear trend and the slope, dα(x)/dx, increased from 2.2 to 7.3 for the graded samples. Moreover, the variation in the conductivity values decreased two orders of magnitude (from 3×10⁻² to 6×10⁻⁴), which also may have contributed in the significant improvement in ΔT.

Overall, we describe herein a facile process in fabricating continuously graded PBTTT thin films by sequential doping of F4TCNQ from the vapor phase. The lateral dopant composition was characterized by GIWAXS experiments, where we observed a gradual change in both side-chain stacking and π-π stacking distances across the graded film. This gradient in dopant composition was confirmed by spatial conductivity measurements through arrays of microelectrodes and was yielded to be about 4 mm wide. Moreover, spatial transport properties (σ and α) were measured across the gradient. Lastly, coupled with mathematical transport models, we predicted the thermoelectric (TE) performance of our continuously graded films based on the experimental results. Cooling temperature (ΔT) and coefficient of performance (C.O.P.) were calculated to characterize the cooling performance as a TE leg. The results demonstrated significant enhancement in the ΔT of our graded samples compared to that of uniform profile. Accordingly, we understand that semiconducting polymers as FGMs are an enabling platform that could further advance the understanding of structure-transport properties and the development of more efficient organic thermoelectric devices.

### Example 6: Experimental Methods

Materials: Poly(2,5-bis(3-tetradecylthiophen-2-yl)thieno[3,2-b]thiophene) (PBTTT, Mw 40,000-80,000) and anhydrous chlorobenzene (CB) was purchased from Sigma-Aldrich (St. Louis, Mo.) and used as received without further purification. 2,3,5,6-Tetrafluoro-7,7,8,8-tetracyanoquinodimethane (F4TCNQ, >98%) was purchased from TCI Chemicals (Tokyo, Japan).

Thin film preparation: Thin film samples for GIWAXS experiments were prepared on silicon with native oxide wafer substrates (15 mm×15 mm×0.5 mm, University Wafer, Inc., South Boston, Mass.). Thin film samples for electrical characterization were prepared on quartz substrates (15 mm×15 mm×0.5 mm, University Wafer). All substrates were cleaned by sonicating in acetone and isopropanol for 10 minutes (min) each, followed by plasma-cleaning for 3 min. For neat PBTTT thin film preparation, PBTTT was dissolved in anhydrous CB (10 mg/mL), and the solution was heated at 80° C. for 2 hours to fully dissolve the polymer. Then, thin films were spin-coated using SCS G3P spin coater (Specialty Coating Systems Inc., Indianapolis, Ind.) from the heated solution (80° C.) using a two-step spin condition of 2000 rpm for 40 seconds (s), followed by 3000 rpm for 25 s. Films were heated at 80° C. for 10 min to remove residual solvent. All solution preparation, spin-coating, and drying steps were performed in an argon glovebox. Thickness of neat films were measured via ellipsometry, which was determined to be approximately 30 nm.

Vapor doping process: Vapor doping was performed in an argon glovebox. Approximately 2 mg of F4TCNQ powder was pressed into a pellet (approximately 3 mm in diameter) and placed in an aluminum oxide crucible (outer diameter of 6.8 mm×height of 4 mm from Government Scientific Source Inc., Reston, Va.), which was in turn placed in a glass insert (diameter˜5 cm, height˜4.5 cm). A stainless-steel container was then preheated for 30 min on a hot plate to allow the chamber to reach a steady temperature at 200° C. (measured vial thermocouple at the base of the chamber). The glass insert with the dopant inside was put into the metal chamber to produce dopant vapor.

Grazing incidence wide angle X-ray diffraction: GIWAXS experiments were conducted at the Advanced Photon Source (Argonne National Laboratory) at beamline 8-ID-E. The energy of the incident beam was at 10.91 keV, and a Pilatus 1MF pixel array detector (pixel size=172 μm) was used. The measurement time for one image was 10 s. All samples were placed and measured in a low vacuum chamber (10⁻³ mbar) to reduce the air scattering as well as to minimize beam radiation damage. There were multiple rows of inactive pixels between the detector modules when the images were collected at one position. To fill these inactive gaps, the detector was moved down to a pre-set new position along the vertical direction after each measurement. After the image was collected at the new spot, the data from these two detector positions were combined using the GIXSGUI package for MATLAB to fill the inactive gaps. The absence of artifacts in the combined image demonstrated that the scattering from the sample does not change during the exposure. The GIXSGUI package was also used to output the GIWAXS signals as intensity maps in (qᵣ, q_{z}) space, and take the linecuts along out-of-plane (q_{z}) and in-plane directions (qᵣ).

GIWAXS images of continuously graded thin films were taken at a grazing incident X-ray angle of 0.14°, which was above the critical angle of the polymer film and below the critical angle of the silicon substrate. GIWAXS images were measured laterally across 30 different spots for the graded films. Measurements were conducted laterally across the interface of the segmented films. The distance between adjacent spots is 200 μm, which is the width of the X-ray beam.

Conductivity and Seebeck measurements: Gold electrical contacts (75 nm thick) for electronic conductivity (a) and Seebeck coefficient (a) measurements were deposited onto either uniform or continuously graded PBTTT thin films via thermal evaporation through shadow masks designed in our lab. Electronic conductivity was measured in the in-plane direction using four probe geometry with a 0.2 mm spacing between electrodes and with electrodes having a length of 1 mm. Seebeck coefficient was measured with two 1 mm² gold pads, which are 1 mm apart. A detailed schematic is provided in FIG. 8. Four probe conductivity measurements were performed using a custom-designed probe station in an argon glovebox. Voltage and current measurements were performed using a Keithley 2400 source meter and Keithley 6221 precision current source. A constant current was applied to the outer contacts, and the resultant steady-state voltage response was recorded from the two inner contacts. The resistance R [Ω] of the sample was extracted from the slope of the IV sweep using Ohm's law (V=IR). The thin film conductivity σ was then calculated using the following equation:

$$σ = \frac{ln 2}{π hR} ,$$

where h=30 nm is the thickness of the sample.

The Seebeck coefficient measurements were performed on the same probe station. Two Peltier elements were placed 5 mm apart to provide the temperature difference (ΔT=T_{H}−T_{C}). Two thermocouples were used to collect the hot and cold side temperatures, and two probes were used to measure the corresponding voltage value. A minimal amount of thermally conductive silicone paste was applied to the tips of the thermocouple to ensure good thermal contact between the thermocouple and the gold pads. A delay of 200 s was used for voltage measurements to ensure that a steady-state temperature gradient and voltage was reached.

The spatial measurements of the electronic conductivity were performed using an array of interdigitated electrodes (IDEs). Interdigitated electrode devices were fabricated at the Pritzker Nanofabrication Facility, University of Chicago (as described below). The measurements were performed using DC measurement method. The extracted resistance R was then used to calculate the electronic conductivity α_{IDE} according to the following equation:

$${σ}_{I D E} = \frac{1}{R} \frac{d}{l ( N - 1 ) h} ,$$

in which d=8 μm is the separation distance between electrodes, l=100 μm is the electrode length, N=40 is the number of electrodes, and h=30 nm is the thickness of the film.

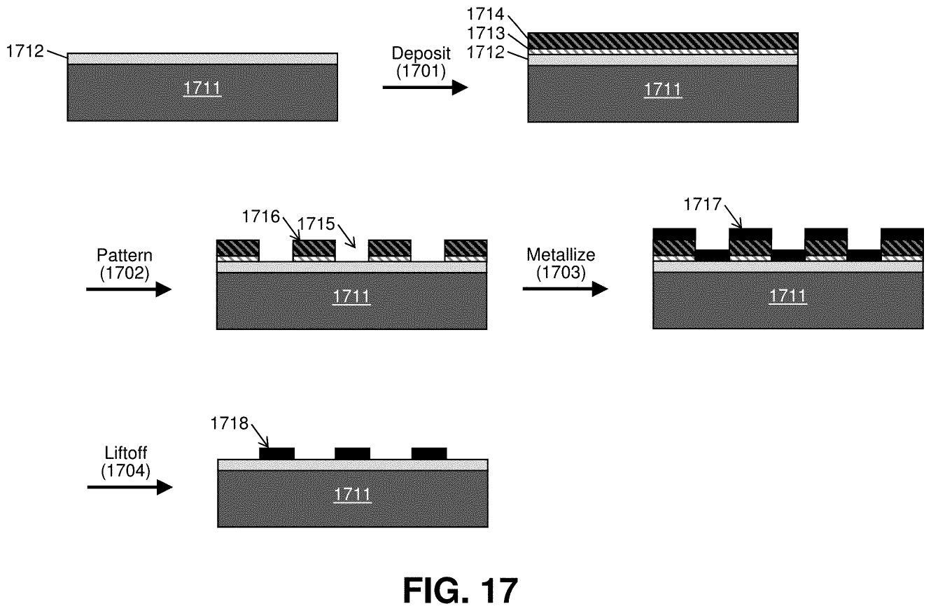

Interdigitated electrode (IDE) fabrication: The workflow for fabrication of the IDEs is shown in FIG. 17. As can be seen, the workflow included providing a silicon wafer 1711 with 1 μm of thermal oxide 1712, which was first cleaned with a 300 W oxygen plasma. Then, layers of hexamethyldisilazane (HAMIDS) and photoresist were deposited 1701 on the wafer. In particular, a monolayer of HMDS 1713 was vapor deposited on the wafer in a vacuum oven at 110° C. under N₂ flow to promote photoresist adhesion. AZ® nLOF™ 2020 negative photoresist 1714 (Merck KGaA, Darmstadt, Germany) was spun cast at 3500 rpm for 45 seconds onto the wafer.

Next, the photoresist was patterned 1702. In particular, the IDE pattern was written with a Heidelberg MLA150 Direct Write Lithographer (Heidelberg Instruments Mikrotechnik GmbH, Heidelberg, Germany), providing exposure with a 375 nm laser; and AZ® 300 MIF developer (tetramethylammonium hydroxide in water) was used to remove the patterned areas of the photoresist. The pattern on the substrate included opened areas 1715 (about 2 μm wide) and pillars 1716 of photoresist. Metallization 1703 was performed to deposit a metal layer 1717 onto the photoresist pattern. Of note, e-beam evaporation of 5 nm titanium was followed by 95 nm of gold, which was then applied to create the electrodes using an Angstrom EvoVac electron-beam evaporator (Angstrom Engineering Inc., Ontario, Canada). Finally, liftoff 1704 of the excess metal and removal of the remaining photoresist was achieved by soaking the wafer in an 80° C. bath of n-methyl-2-pyrrolidone (NMP) overnight followed by sonication in fresh NMP. Wafers were subsequently rinsed with acetone, isopropyl alcohol (IPA), and deionized water to provide electrodes 1718 patterned on the surface of the wafer 1711. A single 4″ wafer contained as many as 24 IDE devices.

### OTHER EMBODIMENTS

All publications, patents, and patent applications mentioned in this specification are incorporated herein by reference to the same extent as if each independent publication or patent application was specifically and individually indicated to be incorporated by reference.

While the invention has been described in connection with specific embodiments thereof, it will be understood that it is capable of further modifications and this application is intended to cover any variations, uses, or adaptations of the invention following, in general, the principles of the invention and including such departures from the present disclosure that come within known or customary practice within the art to which the invention pertains and may be applied to the essential features hereinbefore set forth, and follows in the scope of the claims.

Other embodiments are within the claims.

1. A functionally graded thermoelectric material comprising:
an organic conducting polymer; and
a molecular dopant, wherein the molecular dopant is spatially distributed within the polymer in a continuous manner along at least about 20% of a dimension of the material.

2. The material of claim 1, wherein the polymer is provided as a film, and optionally wherein the film has a thickness of from about 10 nm to 100 nm.

3. The material of claim 1, wherein the molecular dopant is spatially distributed in a controlled pattern across a surface of the polymer.

4. The material of claim 3, wherein the controlled pattern comprises a linear gradient, a step gradient comprising a plurality of steps, a sigmoidal gradient, or a bell curve gradient.

5. The material of claim 3, wherein the controlled pattern extends over the surface of the polymer along a dimension of from about 2, 3, 4, 5, 10, 15, 20 mm, or more; or along at least 40%, 50%, 60%, 70%, 80%, or 90% of a linear dimension of the material.

6. The material of claim 1, wherein the polymer comprises a conjugated polymer.

7. The material of claim 1, wherein the polymer is capable of being cast onto a substrate from a solution.

8. The material of claim 1, wherein the polymer comprises an optionally substituted thiophene, an optionally substituted thienothiophene, an optionally substituted isothianaphthene, an optionally substituted ethylenedioxythiophene, or a combination thereof.

9. The material of claim 8, wherein the polymer is substituted with optionally substituted C₃₋₂₄ alkyl, optionally substituted C₃₋₂₄ thioalkyl, halo, or a combination thereof.

10. The material of claim 1, wherein the dopant sublimes at a temperature of from about 150° C. to about 250° C. at an ambient pressure; and/or wherein the dopant is capable of being introduced to the polymer in a vapor phase.

11. The material of claim 10, wherein the dopant comprises a p-type dopant.

12. The material of claim 11, wherein the dopant comprises an optionally substituted quinodimethane, an optionally substituted naphthoquinodimethane, an optionally substituted perylene, or an ion thereof.

13. The material of claim 12, wherein the dopant is substituted with a halo, a fluoro, a cyano, an ester, or a combination thereof.

14. A device comprising at least one thermoelectric element, wherein the thermoelectric element comprises:
a first interconnect and a second interconnect, wherein each of the first and second interconnects comprise, independently, a conductive material; and
a functionally graded thermoelectric material that is electrically connected to the first and second interconnects,
wherein the functionally graded thermoelectric material comprises an organic conducting polymer and a molecular dopant, and
wherein the molecular dopant is spatially distributed within the polymer in a continuous manner along at least about 20% of a dimension of the material.

15. The device of claim 14, further comprising a plurality of thermoelectric elements that are electrically connected in series and thermally connected in parallel.

16. The device of claim 14, wherein the molecular dopant is an n-type dopant, and wherein the device further comprises:
a p-type thermoelectric material that is electrically connected to the second interconnect and a third interconnect, wherein the third interconnect comprises a conductive material.

17. A method of making a functionally graded thermoelectric material, the method comprising:
introducing a molecular dopant to an organic conducting polymer, wherein the molecular dopant is in a vapor form, and wherein the molecular dopant is spatially distributed within the polymer in a continuous manner along at least about 20% of a dimension of the material.

18. The method of claim 17, wherein the molecular dopant is spatially distributed within the polymer.

19. The method of claim 18, further comprising, prior to said introducing:
depositing a solution comprising the polymer on a surface of a substrate, thereby forming a film, and
wherein said introducing comprises introducing the molecular dopant to the film.

20. The method of claim 19, further comprising, after said depositing but prior to said introducing:
covering a surface of the film with a mask, thereby providing an exposed portion.

21. The method of claim 20, wherein the mask is in contact with the surface of the film, or wherein the mask is separated from the surface of the film by a distance of from about 5 μm to about 100 μm.

22. The method of claim 21, wherein the mask has a wedge geometry, in which a side of the wedge forms a proximal surface in proximity to the surface of the film.

23. The method of claim 22, wherein a region between the proximal surface of the mask and the surface of the film provides a constrained region accessible to the dopant.

24. The method of claim 20, wherein said introducing comprises:
introducing the molecular dopant to the exposed portion of the film.

25. The method of claim 24, wherein the molecular dopant is spatially distributed in a controlled pattern across the surface of the polymer; and optionally wherein the controlled pattern comprises linear gradient, a step gradient, a sigmoidal gradient, or a bell curve gradient.

26. The method of claim 17, wherein the polymer comprises a conjugated polymer, an optionally substituted thiophene, an optionally substituted thienothiophene, an optionally substituted isothianaphthene, an optionally substituted ethylenedioxythiophene, or a combination thereof.

27. The method of claim 26, wherein the polymer is substituted with optionally substituted C₃₋₂₄ alkyl or optionally substituted C₃₋₂₄ thioalkyl.

28. The method of claim 17, wherein said introducing further comprises heating the dopant to a temperature to promote sublimation of the dopant.

29. The method of claim 17, wherein said introducing further comprises delivering the dopant in a vapor form to a chamber comprising the polymer.

30. The method of claim 17, wherein the dopant comprises a p-type dopant.

31. The method of claim 30, wherein the dopant comprises an optionally substituted quinodimethane, an optionally substituted naphthoquinodimethane, or an ion thereof.

32. The method of claim 31, wherein the dopant is substituted with a halo, a fluoro, a cyano, an ester, or a combination thereof.
